(19) United States
(12) Patent Application Publication
(10) Pub. No.: US 2026/0143674 A1
(43) Pub. Date: May 21, 2026

(54) SEMICONDUCTOR DEVICES AND METHOD OF MANUFACTURING THE SAME

(71) Applicant: Samsung Electronics Co., Ltd., Suwon-si (KR)

(72) Inventors: Juho Lee, Suwon-si (KR); Seungwon Lee, Suwon-si (KR); Wooje Jung, Suwon-si (KR); Kyongjun Yoo, Suwon-si (KR); Sungduk Hong, Suwon-si (KR)

(21) Appl. No.: 19/274,794

(22) Filed: Jul. 21, 2025

(30) Foreign Application Priority Data
Nov. 18, 2024 (KR) 10-2024-0164389

(51) Int. Cl. H10B 12/00; H01L 23/00; H01L 25/00; H01L 25/065; H01L 25/18; H10B 80/00

(52) U.S. Cl. CPC H10B 12/315; H10B 12/05; H10B 80/00; H10W 90/00; H10W 80/312; H10W 80/327; H10W 90/792

(57) ABSTRACT

A semiconductor device including a peripheral circuit area and a cell array area, where the cell array area includes a mold structure extending in a first horizontal direction, a channel layer on a sidewall of the mold structure, where the channel layer includes a first oxide semiconductor material, a word line on a sidewall of the channel layer, a landing pad on a top surface of the channel layer, a bit line on a bottom surface of the channel layer opposite the top surface, where the bit line extends in a second horizontal direction that intersects the first horizontal direction, an oxide semiconductor layer on one or more sidewalls and a bottom surface of the landing pad, where the oxide semiconductor layer including a second oxide semiconductor material, and a cell capacitor electrically connected to the channel layer through the landing pad and the oxide semiconductor layer.

### CROSS-REFERENCE TO RELATED APPLICATION

This application is based on and claims priority under 35 U.S.C. § 119 to Korean Patent Application No. 10-2024-0164389, filed on Nov. 18, 2024, in the Korean Intellectual Property Office, the disclosure of which is herein incorporated by reference in its entirety.

### TECHNICAL FIELD

The inventive concept relates to a semiconductor device and a method of manufacturing the same, and more particularly, to a semiconductor device including vertical channel transistors and a method of manufacturing the semiconductor device.

### BACKGROUND

As semiconductor devices are downscaled, the size of dynamic random-access memory (DRAM) devices is also reduced. In addition, as DRAM devices having a 1T-1C structure (in which one transistor is connected to one capacitor) become smaller, a leakage current through a channel region increases.

### SUMMARY

The inventive concept provides a semiconductor device having improved electrical performance.

The inventive concept provides a method of manufacturing the semiconductor device having improved electrical performance.

However, the inventive concept is not limited to those mentioned above. Other inventive concepts may be clearly understood by those skilled in the art from the following descriptions.

According to an aspect of the inventive concept, there is provided a semiconductor device, including a peripheral circuit area, and a cell array area on the peripheral circuit area, where the cell array area includes a mold structure extending in a first horizontal direction, a channel layer on a sidewall of the mold structure, where the channel layer includes a first oxide semiconductor material, a word line on a sidewall of the channel layer, a landing pad on a top surface of the channel layer, a bit line on a bottom surface of the channel layer opposite the top surface, where the bit line extends in a second horizontal direction that intersects the first horizontal direction, an oxide semiconductor layer on one or more sidewalls and a bottom surface of the landing pad, where the oxide semiconductor layer includes a second oxide semiconductor material, and a cell capacitor electrically connected to the channel layer through the landing pad and the oxide semiconductor layer.

According to an aspect of the inventive concept, there is provided a semiconductor device, including a peripheral circuit area including a substrate and a peripheral circuit transistor, and a cell array area on the peripheral circuit area, where the cell array area includes a mold structure extending in a first horizontal direction, a channel layer on a sidewall of the mold structure, where the channel layer including a first oxide semiconductor material, a word line on a sidewall of the channel layer, a gate insulating layer between the channel layer and the word line, a landing pad on a top surface of the channel layer, an oxide semiconductor layer on one or more sidewalls and a bottom surface of the landing pad, where the oxide semiconductor layer includes a second oxide semiconductor material, a cell capacitor separated from the channel layer in a vertical direction by the landing pad and the oxide semiconductor layer, a bit line on a bottom surface of the channel layer opposite the top surface and extending in a second horizontal direction that intersects the first horizontal direction, a bit line insulating layer on the bit line, and a shield metal layer separated from the bit line by the bit line insulating layer.

According to an aspect of the inventive concept, there is provided a method of manufacturing a semiconductor device, the method including forming a peripheral circuit area and forming a cell array area on the peripheral circuit area, where the forming of the cell array area includes forming a cell capacitor and a first insulating layer on a sidewall of the cell capacitor on a carrier substrate, forming a landing pad on the cell capacitor, forming a first oxide semiconductor layer on one or more sidewalls of the landing pad, forming a second insulating layer on the first oxide semiconductor layer, performing an etch-back process on a top surface of the landing pad to form a landing pad recess, forming a second oxide semiconductor layer in the landing pad recess, and forming a mold structure on the first oxide semiconductor layer, the second oxide semiconductor layer, and the second insulating layer, forming a channel layer on a sidewall of the mold structure, forming a word line on a sidewall of the channel layer, and forming a bit line on a bottom surface of the channel layer.

### BRIEF DESCRIPTION OF THE DRAWINGS

Embodiments will be more clearly understood from the following detailed description taken in conjunction with the accompanying drawings in which:

FIG. 1 is a schematic diagram of a semiconductor device according to some embodiments;

FIG. 2 is an enlarged layout view of a cell array area of FIG. 1;

FIG. 3 is a cross-sectional view taken along line A1-A1′ in FIG. 2;

FIG. 4 is a cross-sectional view taken along line A2-A2′ in FIG. 2;

FIG. 5 is an enlarged view of portion CX1 in FIG. 3;

FIG. 6A is a diagram of a semiconductor device according to some embodiments;

FIG. 6B is a diagram of a semiconductor device according to some embodiments;

FIGS. 7 and 8 are diagrams of a semiconductor device according to some embodiments;

FIG. 9 is an enlarged view of portion CX2 in FIG. 7;

FIG. 10 is a schematic diagram of a landing structure according to some embodiments;

FIGS. 11A 11B, 12A, 12B, 13A, 13B, 14A, 14B, 15A, 15B, 16A, 16B, 17A, 17B, 18A, 18B, 18C, 19A, 19B, 19C, 20A, 20B, 20C, 21A, 21B, 21C, 22A, 22B, 23A, 23B, 24A, 24B, 25A, 25B, 25C, 26A, 26B, 26C, 27, 28 and 29 are diagrams sequentially illustrating a method of manufacturing a semiconductor device, according to some embodiments; and

FIGS. 30A, 30B, 31A, 31B, 32A, 32B and 32C are diagrams sequentially illustrating a method of manufacturing a semiconductor device, according to some embodiments.

### DETAILED DESCRIPTION OF EMBODIMENTS

Hereinafter, embodiments are described in detail with reference to the accompanying drawings. The same reference numerals are used for the same components in the drawings, and redundant descriptions thereof are omitted.

The term “first,” “second,” or the like used herein may modify various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween.

The term “overlap,” when used herein may specify the position of an element as on, in contact with, and/or covering another element. Components or layers described with reference to “overlap” in a particular direction may be at least partially obstructed by one another when viewed along a line extending in the particular direction or in a plane perpendicular to the particular direction. The term “in contact with” may be used herein to specify an element or layer that is directly on another element or layer without the presence of at least one additional element or layer therebetween. The term “fill,” “filling,” or the like as used herein, may refer to a process in which an element or component may partially, completely, or over fill a void or cavity. The term “surrounding,” “covering” or the like used herein may not require completely surrounding or covering the described elements or layers, but may, for example, refer to partially surrounding or covering the described elements or layers, for example, with voids or other spaces throughout. The term “vertical height” as used herein, refers to a height of the elements or components with respect to a common reference element, line, or axis.

A horizontal direction may include a first horizontal direction (e.g., X direction) and a second horizontal direction (e.g., Y direction) that intersect with each other. A direction intersecting the first horizontal direction (e.g., X direction) and the second horizontal direction (e.g., Y direction) may be referred to as a vertical direction (e.g., Z direction). A vertical level may be referred to as a height level in the vertical direction (e.g., Z direction) of any configuration. In addition, hereinafter, a horizontal width of any element or component may refer to a length in the horizontal direction (e.g., X direction and/or Y direction) and a height of any element or component may refer to a length in the vertical direction (e.g., Z direction).

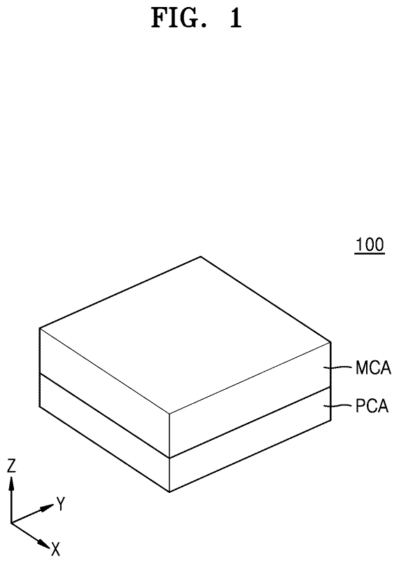

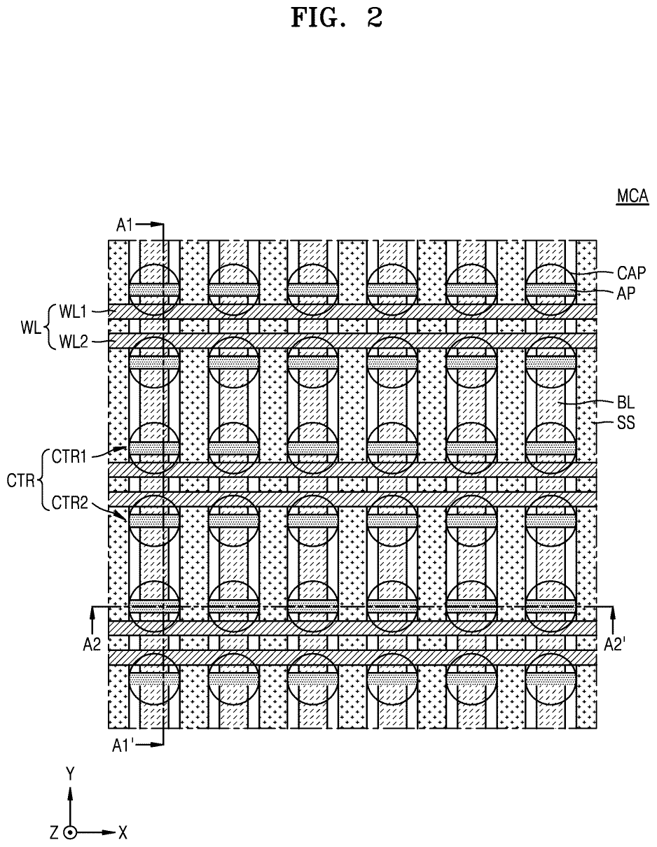

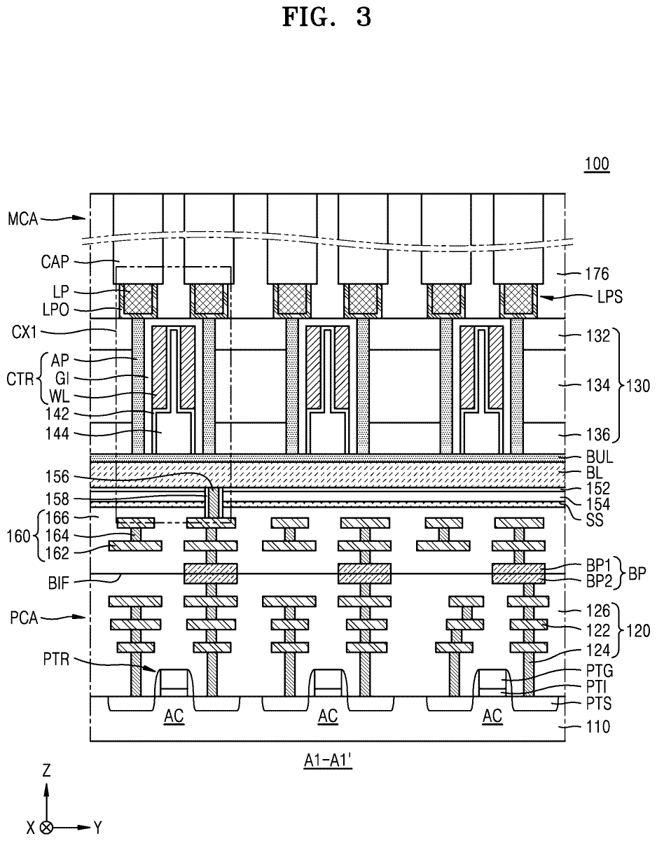

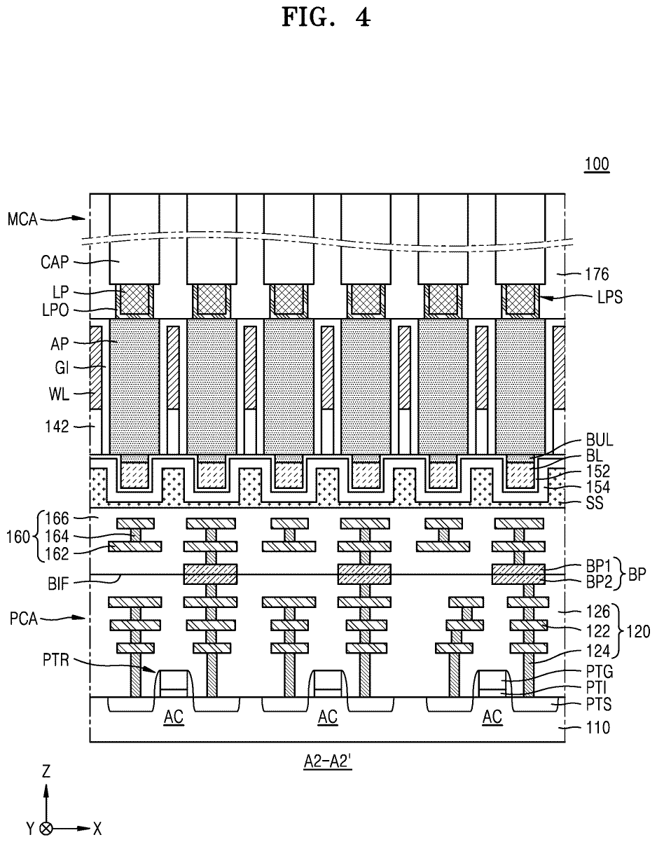

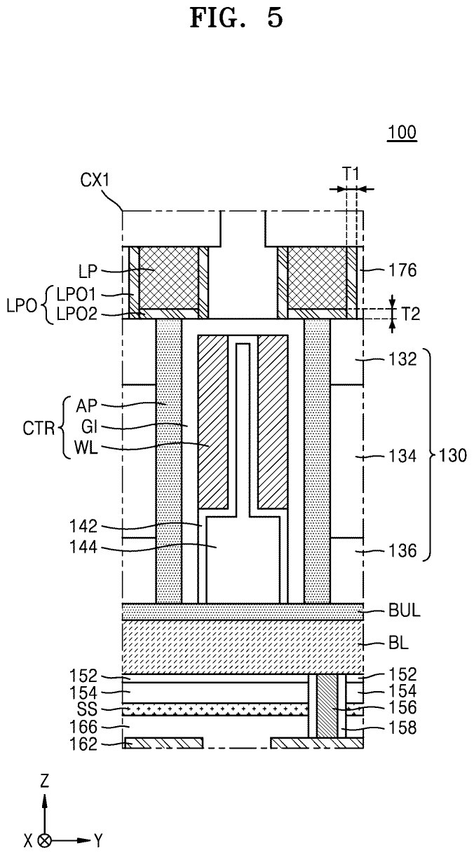

FIG. 1 is a schematic diagram of a semiconductor device 100 according to some embodiments. FIG. 2 is an enlarged layout view of a cell array area MCA in FIG. 1. FIG. 3 is a cross-sectional view taken along line A1-A1′ in FIG. 2. FIG. 4 is a cross-sectional view taken along line A2-A2′ in FIG. 2. FIG. 5 is an enlarged view of portion CX1 of FIG. 3.

Referring to FIGS. 1, 2, 3, 4 and 5, the semiconductor device 100 may include a peripheral circuit area PCA and a cell array area MCA which is arranged at a higher vertical level than the peripheral circuit area PCA. In other words, the cell array area MCA may be on the peripheral circuit area PCA.

In some embodiments, the cell array area MCA may include a memory cell region of a dynamic random-access memory (DRAM) device and the peripheral circuit area PCA may include a core region or a peripheral circuit region of the DRAM device. For example, the peripheral circuit area PCA may include a peripheral circuit transistor PTR transmitting signals and/or power to a memory cell array in the cell array area MCA. In some embodiments, the peripheral circuit transistor PTR may be configured to include various circuits, such as command decoders, control logic, address buffers, row decoders, column decoders, sense amplifiers, and data input/output circuits.

As shown in FIG. 2, a plurality of word lines WL extending in the first horizontal direction (e.g., X direction) and a plurality of bit lines BL extending in the second horizontal direction (e.g., Y direction) may be arranged in the cell array area MCA. A plurality of cell transistors CTR may be arranged at intersections of the plurality of word lines WL and the plurality of bit lines BL. A plurality of cell capacitors CAP may be arranged above the plurality of cell transistors CTR, respectively.

The plurality of word lines WL may include a first word line WL1 and a second word line WL2 alternately arranged in the second horizontal direction (e.g., Y direction). The plurality of cell transistors CTR may include a first cell transistor CTR1 and a second cell transistor CTR2 alternately arranged in the second horizontal direction (e.g., Y direction). The first cell transistor CTR1 may be arranged adjacent to the first word line WL1 and the second cell transistor CTR2 may be arranged adjacent to the second word line WL2. The first cell transistor CTR1 and the second cell transistor CTR2 may have a mirror-symmetric structure with respect to each other. In other words, the first cell transistor CTR1 and the second cell transistor CTR2 may have mirror symmetry such that the order of components is flipped (i.e., reversed or reflected) across a plane of symmetry. For example, the first cell transistor CTR1 and the second cell transistor CTR2 may have a mirror-symmetric structure with respect to a center line (i.e., plane of symmetry) between the first cell transistor CTR1 and the second cell transistor CTR2, wherein the center line extends in the first horizontal direction (e.g., X direction) or second horizontal direction (e.g., Y direction).

In some embodiments, a pitch of the plurality of bit lines BL (e.g., a sum of a width of one bit line BL and an interval between two adjacent bit lines BL) may be 2F. In other words, a distance F may be a width of one bit line BL as well as an interval between two adjacent bit lines BL. A pitch of the first word line WL1 may be 2F and/or a pitch of the second word line WL2 may be 2F. A unit area for forming one cell transistor CTR may be 4F². In other words, the length and the width of one cell transistor CTR may be 2F such that the unit area of the one cell transistor may be 4F².

Vertical channel transistors including an oxide semiconductor material as a channel layer have been proposed to reduce leakage current. Furthermore, vertical channel transistors including an oxide semiconductor material as a channel layer have demonstrated improved electrical performance and reliability. The cell transistor CTR may have a cross-point type (i.e., crossbar architecture) requiring a relatively small unit area, thereby improving the integration of the semiconductor device 100.

Although not shown, an edge region may be arranged around the cell array area MCA. The edge region may include a region where an electrical connection member for the word line WL and/or an electrical connection member for the bit line BL is arranged and a region where an electrical connection member for electrical connection between the cell array area MCA and the peripheral circuit area PCA is arranged.

Hereinafter, as illustrated in FIGS. 3 and 4, a case where the cell array area MCA is arranged at a higher vertical level than the peripheral circuit area PCA (e.g., a case where the cell array area MCA is arranged on the peripheral circuit area PCA) is described. However, the semiconductor device 100 may be arranged upside down such that the cell array area MCA is located at a lower vertical level than the peripheral circuit area PCA. In this case, spatially relative terms such as a “top surface” or a “bottom surface” of the components in the following description should be understood to refer to a “bottom surface” or a “top surface” of the components, respectively. The components described as being “above” or “below” any component should be understood as being “below” or “above” any component, respectively. The components described as being “arranged at a higher vertical level” than any component should be understood as being “arranged at a lower vertical level” than any component. It will be understood that such spatially relative terms are intended to encompass different orientations of the device in use or operation in addition to the orientation depicted in the figures.

A substrate 110 may include silicon, for example, single crystal silicon, polycrystalline silicon, or amorphous silicon. In some embodiments, the substrate 110 may include at least one selected from germanium (Ge), silicon-germanium (SiGe), silicon carbide (SiC), gallium arsenide (GaAs), indium arsenide (InAs), and/or indium phosphide (InP). In some embodiments, the substrate 110 may include a conductive region (e.g., an impurity-doped well or an impurity-doped structure).

In the peripheral circuit area PCA, an active region AC may be defined in the substrate 110 and a peripheral circuit transistor PTR may be disposed on the active region AC of the substrate 110. The peripheral circuit transistor PTR may include a gate electrode PTG, a gate insulating layer PTI, and a source/drain region PTS.

The peripheral circuit transistor PTR may be disposed on the substrate 110. A peripheral circuit wiring structure 120 may be disposed on the peripheral circuit transistor PTR. The peripheral circuit wiring structure 120 may include a peripheral circuit wiring 122, a peripheral circuit contact 124, and a peripheral circuit insulating layer 126. The peripheral circuit wiring 122 and the peripheral circuit contact 124 may be electrically connected to the peripheral circuit transistor PTR and/or the substrate 110, and the peripheral circuit insulating layer 126 may cover the peripheral circuit transistor PTR, the peripheral circuit wiring 122, and the peripheral contact 124 on the substrate 110. The peripheral circuit insulating layer 126 may include an oxide film, a nitride film, a low dielectric film, and/or combinations thereof and may be formed of a stacked-layer structure of a plurality of insulating layers.

The peripheral circuit area PCA may be attached to the cell array area MCA by a bonding method. In some embodiments, the boundary between the peripheral circuit area PCA and the cell array area MCA may be referred to as a bonding interface BIF. For example, a portion of the semiconductor device 100 arranged at a lower vertical level than the bonding interface BIF illustrated in FIG. 3 may be referred to as the peripheral circuit area PCA, and a portion of the semiconductor device 100 arranged at a higher vertical level than the bonding interface BIF may be referred to the cell array area MCA.

In some embodiments, the peripheral circuit wiring structure 120 may be in contact with a cell wiring structure 160 with the bonding interface BIF therebetween. The cell wiring structure 160 may include a cell wiring layer 162, a cell contact 164, and a cell insulating layer 166.

A bonding pad BP may be arranged at an interface (e.g., the bonding interface BIF) between the cell wiring structure 160 and the peripheral circuit wiring structure 120. The bonding pad BP may include a first bonding pad BP1 and a second bonding pad BP2. A bottom surface of the first bonding pad BP1 may be arranged at the same level (i.e., height) as a bottom surface of the cell insulating layer 166 and a top surface of the second bonding pad BP2 may be arranged at the same level (i.e., height) as a top surface of the peripheral circuit insulating layer 126, wherein the top surface of the second bonding pad BP2 may be in partial or complete contact with the bottom surface of the first bonding pad BP1.

In some embodiments, the cell wiring structure 160 may be bonded to the peripheral circuit wiring structure 120 by a metal-oxide hybrid bonding method. In this case, an interface between the peripheral circuit insulating layer 126 and the cell insulating layer 166 may be arranged on the same plane as (i.e., coplanar with) an interface between the first bonding pad BP1 and the second bonding pad BP2 (e.g., an interface between the peripheral circuit insulating layer 126 and the cell insulating layer 166 and an interface between the first bonding pad BP1 and the second bonding pad BP2 may be arranged along the bonding interface BIF). The plane (i.e., bonding interface BIF) which serves as the interface may extend in a horizontal direction (e.g., an X direction or Y direction).

In some embodiments, the cell wiring structure 160 may be bonded to the peripheral circuit wiring structure 120 by an oxide bonding method. In this case, the bonding pad BP may be omitted.

The plurality of bit lines BL may be disposed above the cell wiring structure 160. The cell transistor CTR may be disposed on the plurality of bit lines BL. The cell capacitor CAP may be disposed on the cell transistor CTR. In some embodiments, the bit line BL may be arranged closer to the bonding interface BIF than the cell transistor CTR or the cell capacitor CAP. Accordingly, the vertical distance between the bit line BL and the peripheral circuit transistor PTR may be less than the vertical distance between the cell capacitor CAP and the peripheral circuit transistor PTR.

In some embodiments, the plurality of bit lines BL may extend in the second horizontal direction (e.g., Y direction) and may be arranged such that a shield metal layer SS partially or completely fills spaces between the plurality of bit lines BL. For example, the plurality of bit lines BL may extend in the second horizontal direction (e.g., Y direction). Some portions of the shield metal layer SS may partially or completely fill the spaces between the plurality of bit lines BL and extend in the second horizontal direction (e.g., Y direction) and the other portions of the shield metal layer SS may be arranged between the bottom surfaces of the plurality of bit lines BL and the top surface of the cell wiring structure 160. The sidewalls and the bottom surfaces of the bit lines BL may be covered by a first bit line insulating layer 152 and a second bit line insulating layer 154. The first bit line insulating layer 152 and the second bit line insulating layer 154 may be arranged between the sidewalls of the bit lines BL and the shield metal layer SS as well as between the bottom surfaces of the bit lines BL and the shield metal layer SS.

In some embodiments, the bit lines BL may include titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), polysilicon, and/or combinations thereof. In some embodiments, the shield metal layer SS may include Ti, TiN, Ta, TaN, Mo, Ru, W, WN, Co, Ni, Cu, Al, TiSi, TiSiN, WSi, WSiN, TaSi, TaSIN, RuTiN, CoSi, NiSi, and/or combinations thereof.

A bit line contact 156 may be arranged between a bottom surface of the bit line BL and the cell wiring layer 162, wherein sidewalls of the bit line contact 156 may be surrounded by a bit line contact spacer 158. The bit line contact 156 may be electrically insulated from the shield metal layer SS by the bit line contact spacer 158.

A plurality of intermediate lines BUL may be disposed on top surfaces of the plurality of bit lines BL, respectively. The plurality of intermediate lines BUL may extend in the second horizontal direction (e.g., Y direction) and may cover the top surfaces of the plurality of bit lines BL, respectively. The sidewalls of the plurality of intermediate lines BUL may be covered by the first bit line insulating layer 152.

In some embodiments, the plurality of intermediate lines BUL may include the oxide semiconductor. For example, the oxide semiconductor material may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), and/or zirconium zinc tin oxide (Zr_{X}Zn_{y}Sn_{z}O). In some embodiments, the plurality of intermediate lines BUL may include semiconductor materials, such as Si, Ge, and/or SiGe. In some embodiments, the plurality of intermediate lines BUL may further include n-type impurity ions. For example, the n-type impurity ions may be doped into the plurality of intermediate lines BUL through an ion implantation process or the like.

In some embodiments, the sidewalls of each of the plurality of intermediate lines BUL may be aligned with the sidewalls of each of the plurality of bit lines BL. In some embodiments, each of the plurality of intermediate lines BUL may have a first width in the first horizontal direction (e.g., X direction) and each of the plurality bit lines BL may have a second width in the first horizontal direction (e.g., X direction), wherein the first width may be the same as or similar to the second width. That the first width is the same as or similar to the second width may mean that the second width has a value within a tolerance range (i.e., error margin) from the first width (e.g., a value within a range of a tolerance or an acceptable error during the manufacturing process, such as a value within ±5% or ±10% difference compared to the first width).

In some embodiments, the plurality of intermediate lines BUL may be patterned together during a patterning process of the plurality of bit lines BL. For example, an intermediate line layer BULp (see FIGS. 24A and 24B) and the bit line layer BLp (see FIGS. 24A and 24B) may be sequentially formed on a mold structure 130 and a cell transistor CTR, and then the intermediate line layer BULp and the bit line layer BLp may be patterned into a line type to form the plurality of intermediate lines BUL and the plurality of bit lines BL. In this case, sidewalls of each of the plurality of intermediate lines BUL may be aligned with sidewalls of each of the plurality of bit lines BL.

In some embodiments, during the patterning process for forming the plurality of intermediate lines BUL and the plurality of bit lines BL, portions of the plurality of bit lines BL may be exposed to the etching atmosphere for a long time. In this case, the sidewalls of the plurality of bit lines BL may be inclined at a certain angle.

In some embodiments, the bit line BL may have a flat top surface level and a flat bottom surface level. For example, the bit line BL may have a uniform thickness in the vertical direction (e.g., Z direction) over its entire length in the second horizontal direction (e.g., Y direction). In addition, the intermediate line BUL may have a flat top surface level and a flat bottom surface level. For example, the intermediate line BUL may have a uniform thickness in the vertical direction (e.g., Z direction) over its entire length in the second horizontal direction (e.g., Y direction).

With the intermediate line BUL arranged between the bit line BL and a channel layer AP, the electrical resistance between the bit line BL and the channel layer AP may be significantly reduced, thereby improving the electrical performance.

The plurality of mold structures 130 and the plurality of cell transistors CTR may be arranged on top surfaces of the plurality of intermediate lines BUL. For example, the plurality of mold structures 130 may each extend in the first horizontal direction (e.g., X direction), and the plurality of cell transistors CTR may be disposed on both sidewalls of each mold structure 130.

Each of the plurality of mold structures 130 may include a first mold layer 132, a second mold layer 134, and a third mold layer 136, each arranged in the vertical direction (e.g., Z direction). For example, the third mold layer 136 may be arranged on the intermediate line BUL and the first bit line insulating layer 152. For example, the third mold layer 136 may be in contact with the intermediate line BUL and the first bit line insulating layer 152. The second mold layer 134 may be disposed on the third mold layer 136, and the first mold layer 132 may be disposed on the second mold layer 134.

In some embodiments, each of the first to third mold layers 132, 134, and 136 may include at least one of silicon oxide, silicon nitride, silicon oxynitride, and/or a low-k dielectric material. In some embodiments, the first mold layer 132 and the third mold layer 136 may include silicon nitride and/or silicon oxynitride, and the second mold layer 134 may include silicon oxide and/or a low-k dielectric material.

In some embodiments, the cell transistor CTR may include a channel layer AP, a gate insulating layer GI, and a word line WL, which are sequentially arranged on the sidewalls of the mold structure 130.

In some embodiments, the channel layer AP may extend in the vertical direction (e.g., Z direction) and may have a top surface arranged on the same plane (i.e., coplanar with) as the top surface of the mold structure 130 and a bottom surface arranged on the same plane (i.e., coplanar with) as the bottom surface of the mold structure 130. The bottom surface of the channel layer AP and the bottom surface of the mold structure 130 may be partially or completely in contact with the top surface of the intermediate line BUL.

When the process of forming a recess by removing a portion of the channel layer AP is not performed, the channel layer AP extends in the vertical direction (e.g., Z direction) and the bit line BL has a line shape extending in the second horizontal direction (e.g., Y direction). Thus, the vertical distance between the bit line BL and the shield metal layer SS may be relatively small. Accordingly, since the bit line BL is easily shielded by the shield metal layer SS, a coupling capacitor due to the bit line coupling may be significantly low.

In some embodiments, the channel layer AP may include an oxide semiconductor material, wherein the oxide semiconductor material may include, for example, at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (Zn_{X}ON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), and/or zirconium zinc tin oxide (ZrₓZn_{y}Sn_{z}O). In some embodiments, the channel layer AP may further include n-type impurity ions. For example, the n-type impurity ions may be doped into the channel layer AP through the ion implantation process or the like.

The gate insulating layer GI may be disposed on the sidewall of the channel layer AP. In some embodiments, the gate insulating layer GI may include at least one selected from a ferroelectric material and a high-k dielectric material having a higher dielectric constant than silicon oxide. In some embodiments, the gate insulating layer GI may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO) strontium tantalate bismuth (StTsBiP), bismuth iron oxide (BiFcO), strontium titanium oxide (SrTiO), yttrium oxide (YO), aluminum oxide (AlO), and/or lead scandium tantalum Oxide (PbScTaO).

The word line WL may be disposed on the sidewall of the gate insulating layer GI. In some embodiments, two word lines WL may be spaced apart from each other and extend in the first horizontal direction (e.g., X direction) between two adjacent mold structures 130. A top surface of the word line WL may be covered by the gate insulating layer GI and a bottom surface of the word line WL may be arranged at a higher vertical level (e.g., height) than the bottom surface of the channel layer AP. In some embodiments, the word line WL may include Ti, TiN, Ta, TaN, Mo, Ru, W, WN, TiSiN, WSiN, polysilicon, and/or combinations thereof.

An insulating liner 142 and a buried insulating layer 144 may be arranged between two adjacent word lines WL. The insulating liner 142 may be conformally disposed on sidewalls and bottom surfaces of two adjacent word lines WL and may be arranged between the word lines WL and the buried insulating layer 144 as well as between the gate insulating layer GI and the buried insulating layer 144.

A plurality of landing pads LP and oxide semiconductor layers LPO respectively covering sidewalls and a bottom surface of the plurality of landing pads LP may be disposed on the plurality of cell transistors CTR. In other words, the sidewalls and the bottom surface of each of the plurality of landing pads LP may be surrounded by the oxide semiconductor layer LPO. Any one of the plurality of landing pads LP and the oxide semiconductor layer LPO covering the sidewalls and the bottom surface of the landing pad LP may constitute a landing pad structure LPS. The cell capacitor CAP may be disposed on the landing pad structure LPS.

In some embodiments, the oxide semiconductor layer LPO may include a portion arranged between the cell transistor CTR and the landing pad LP For example, a portion arranged between the channel layer AP and the landing pad LP. The channel layer AP may be in contact with the oxide semiconductor layer LPO and may be spaced apart from the landing pad LP with a portion of the oxide semiconductor layer LPO arranged therebetween. In some embodiments, the channel layer AP may be electrically connected to the landing pad LP through the oxide semiconductor layer LPO and may be electrically connected to the cell capacitor CAP through the oxide semiconductor layer LPO and the landing pad LP.

In some embodiments, the oxide semiconductor layer LPO may conformally extend on the sidewalls and the bottom surface of the landing pad LP. In some embodiments, the sidewalls of the oxide semiconductor layer LPO may be formed with a slope equal to or similar to that of the sidewalls of the landing pad LP. That the sidewalls of the oxide semiconductor layer LPO are formed with the slope equal to or similar to the sidewalls of the landing pad LP may mean that the slope has a value within a tolerance range (e.g., a value within a range of a tolerance or an error margin during the manufacturing process, such as a value within ±5% or ±10% difference compared to the slope of the landing pad LP).

In some embodiments, the vertical level (i.e., height) of the top surface of the oxide semiconductor layer LPO may be the same as the vertical level (i.e., height) of the top surface of the landing pad LP. In other words, the contact surface between the cell capacitor CAP and the oxide semiconductor layer LPO may be located on the same plane as the contact surface between the cell capacitor CAP and the semiconductor layer LPO.

In some embodiments, the landing pad LP may include Ti, TiN, Ta, TaN, W, WN, TiSiN, WSiN, polysilicon, and/or combinations thereof. The cell capacitor CAP may have a metal-insulator-metal type capacitor structure. For example, the cell capacitor CAP may include a first electrode, a second electrode, and a capacitor dielectric layer arranged between the first electrode and the second electrode.

In some embodiments, the oxide semiconductor layer LPO may include the oxide semiconductor. For example, the oxide semiconductor material may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), and/or zirconium zinc tin oxide (Zr_{X}Zn_{y}Sn_{z}O). In some embodiments, the oxide semiconductor layer LPO may further include the n-type impurity ions. For example, the n-type impurity ions may be doped into the oxide semiconductor layer LPO through the ion implantation process or the like.

The oxide semiconductors included in the channel layer AP, the oxide semiconductor layer LPO, and the intermediate line BUL may be defined as a first oxide semiconductor material, a second oxide semiconductor material, and a third oxide semiconductor material, respectively. The first oxide semiconductor, the second oxide semiconductor, and the third oxide semiconductor may each be independently configured and may include oxide semiconductors having the same or different compositions.

As shown in FIG. 5, the oxide semiconductor layer LPO may include first oxide semiconductor layers LPO1 covering or on the sidewalls of the landing pad LP and a second oxide semiconductor layer LPO2 covering or on the bottom surface of the landing pad LP. In some embodiments, a portion of the first oxide semiconductor layers LPO1 may partially or completely overlap with the second oxide semiconductor layer LPO2 in the first horizontal direction (e.g., X direction) and the second horizontal direction (e.g., Y direction), and the other portion thereof may partially or completely overlap with the landing pad LP in the first horizontal directions (e.g., X direction) and the second horizontal direction (e.g., Y direction). In some embodiments, the second oxide semiconductor layer LPO2 may partially or completely overlap with the landing pad LP in the vertical direction (e.g., Z direction). The first oxide semiconductor layers LPO1 may be electrically connected to the channel layer AP through the second oxide semiconductor layer LPO2, and the second oxide semiconductor layer LPO2 may be partially or completely in contact with the channel layer AP to be electrically connected thereto.

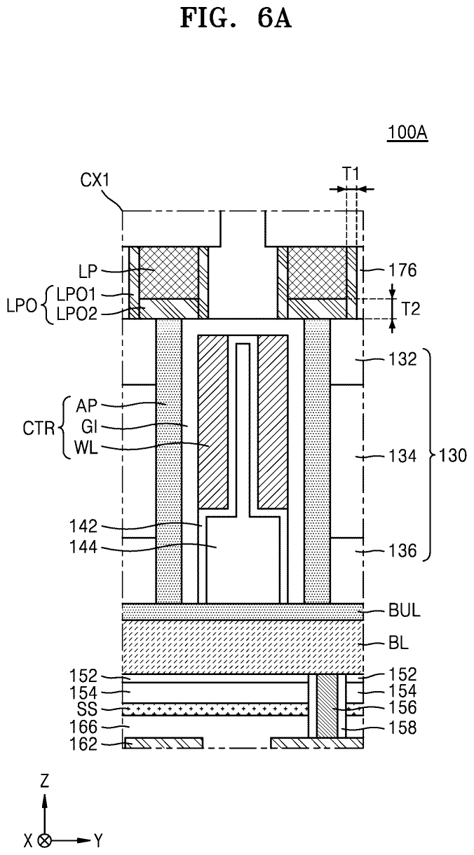

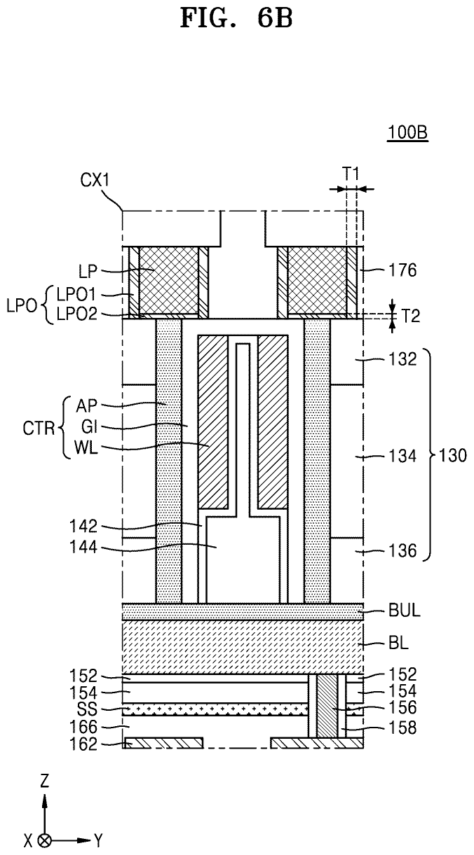

In some embodiments, the first oxide semiconductor layers LPO1 and the second oxide semiconductor layer LPO2 may be formed with same thicknesses. For example, the first oxide semiconductor layers LPO1 may have a first thickness T1 and the second oxide semiconductor layer LPO2 may have a second thickness T2, wherein the first thickness T1 and the second thickness T2 may be the same. However, since the first oxide semiconductor layers LPO1 and the second oxide semiconductor layer LPO2 are formed through separate manufacturing processes, the first oxide semiconductor layers LPO1 and the second oxide semiconductor layer LPO2 may also have different thicknesses. The first oxide semiconductor layers LPO1 and the second oxide semiconductor layer LPO2 which have different thicknesses are described in detail below with reference to FIGS. 6A and 6B.

In some embodiments, the first oxide semiconductor layers LPO1 and the second oxide semiconductor layer LPO2 may include the same material. In some embodiments, the first oxide semiconductor layers LPO1 and the second oxide semiconductor layer LPO2 may include different materials. For example, the first oxide semiconductor layers LPO1 may include zinc tin oxide (ZnₓSn_{y}O) and the second oxide semiconductor layer LPO2 may include indium gallium zinc oxide (InₓGa_{y}Zn_{z}O). Since the first oxide semiconductor layers LPO1 and the second oxide semiconductor layer LPO2 are formed through separate manufacturing processes, the first oxide semiconductor layers LPO1 and the second oxide semiconductor layer LPO2 may be independently formed.

An insulating layer 176 may be disposed on the oxide semiconductor layer LPO and the cell capacitor CAP. The insulating layer 176 may partially or completely cover an outer wall of the oxide semiconductor layer LPO and a portion of the surface of the cell capacitor CAP that is not covered by the landing pad LP and the oxide semiconductor layer LPO. In some embodiments, the insulating layer 176 may be configured as a single-layer structure or a multi-layer structure and may include, for example, silicon oxide, silicon nitride, and/or combinations thereof. For example, as shown in FIG. 13A, the insulating layer 176 may include a first insulating layer 176_1 on or surrounding sidewalls of the cell capacitor CAP and a second insulating layer 176_2 on or surrounding sidewalls of the oxide semiconductor layer LPO. A first insulating layer 176_1 may include silicon oxide and a second insulating layer 177_2 may include silicon nitride. In some embodiments, when hydrogen plasma treatment is performed on the first insulating layer 176_1 and the second insulating layer 176_2, the insulating layer 176 with a relatively high hydrogen content therein may be provided.

FIG. 6A is a diagram of a semiconductor device 100A according to some embodiments.

FIG. 6B is a diagram of a semiconductor device 100B according to some embodiments.

Since the semiconductor devices 100A, 100B of FIGS. 6A and 6B are each configured similarly to the semiconductor device 100 described with reference to FIGS. 1, 2, 3, 4, and 5, differences from the semiconductor device 100 are mainly described below. FIGS. 6A and 6B are enlarged views of portion CX1 in FIG. 3.

Referring to FIGS. 6A and 6B, the semiconductor device 100A may include a plurality of cell transistors CTR (see FIG. 3). A plurality of landing pads LP and a plurality of oxide semiconductor layers LPO respectively on or covering sidewalls and a bottom surface of the plurality of landing pads LP may be disposed on the plurality of cell transistors CTR, respectively.

In some embodiments, the first oxide semiconductor layers LPO1 and the second oxide semiconductor layer LPO2 may be formed with different thicknesses. For example, the first oxide semiconductor layers LPO1 may have a first thickness T1 and the second oxide semiconductor layer LPO2 may have a second thickness T2, wherein the first thickness T1 may be different from the second thickness T2. For example, as shown in FIG. 6A, the first thickness T1 of the first oxide semiconductor layers LPO1 may be less than the second thickness T2 of the second oxide semiconductor layer LPO2. For example, as shown in FIG. 6B, the first thickness T1 of the first oxide semiconductor layers LPO1 may be greater than the second thickness T2 of the second oxide semiconductor layer LPO2. Since the first oxide semiconductor layers LPO1 and the second oxide semiconductor layer LPO2 are each formed through separate manufacturing processes, the first oxide semiconductor layers LPO1 and the second oxide semiconductor layer LPO2 may each be independently formed.

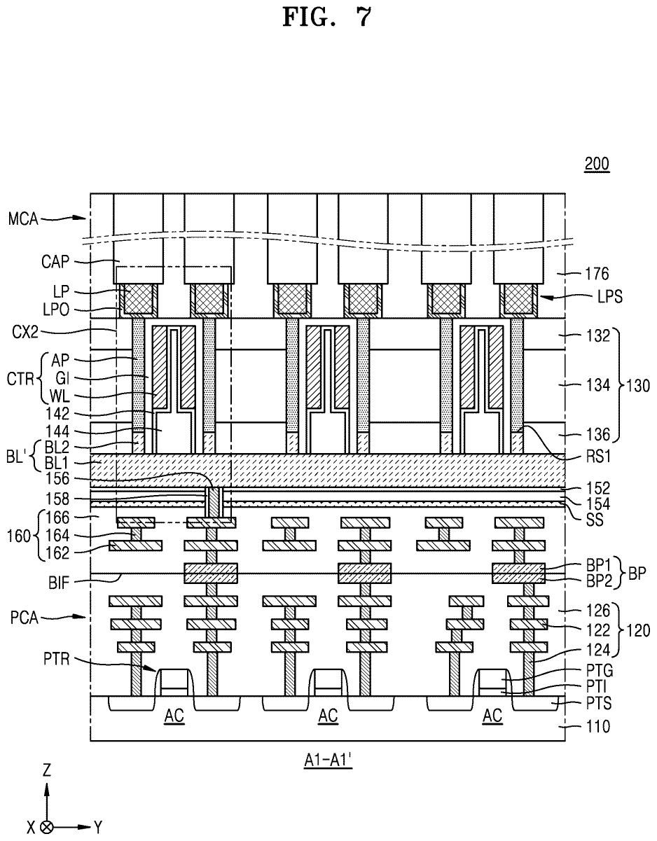

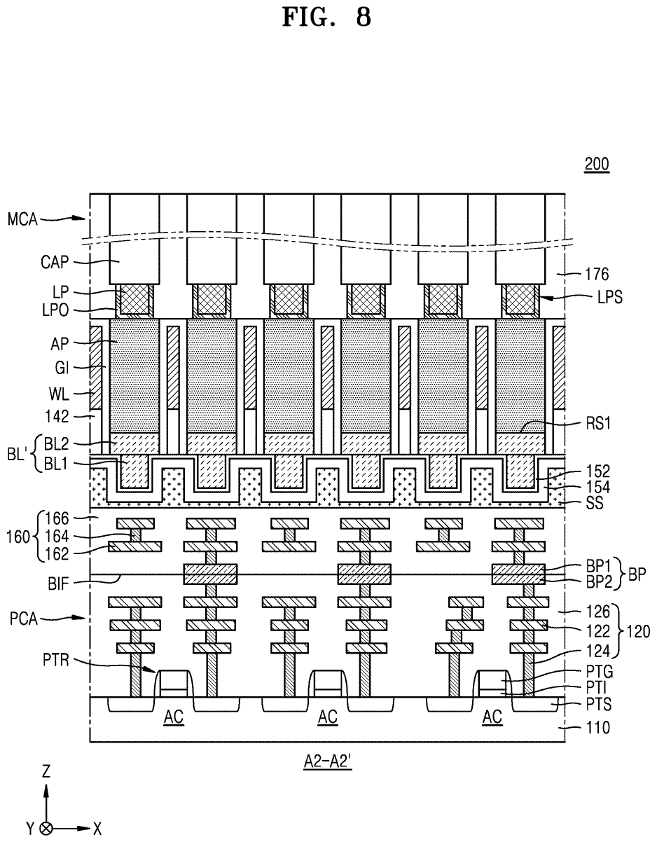

FIGS. 7 and 8 are cross-sectional views of a semiconductor device according to some embodiments.

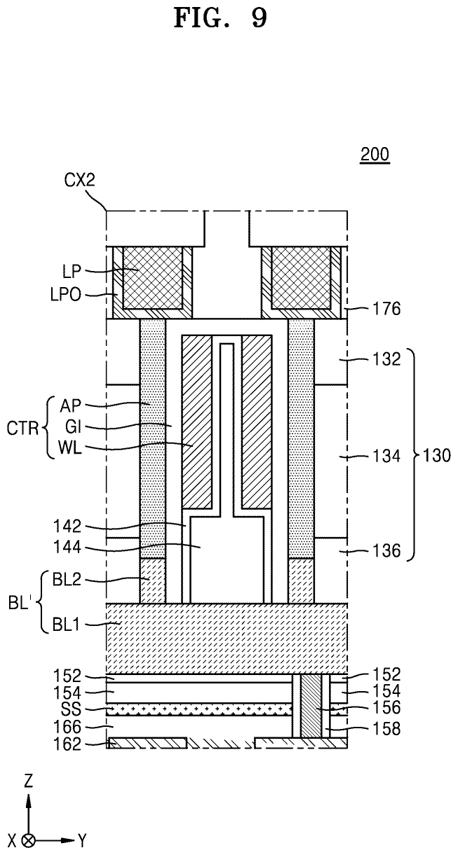

FIG. 9 is an enlarged view of portion CX2 in FIG. 7.

Since a semiconductor device 200 of FIGS. 7 to 9 is configured similarly to the semiconductor device 100 described with reference to FIGS. 1, 2, 3, 4, and 5, differences from the semiconductor device 100 are mainly described below. FIG. 7 is a diagram of a region corresponding to a cross-section taken along line A1-A1′ in FIG. 2 and FIG. 8 is a diagram of a region corresponding to a cross-section taken along line A2-A2′ in FIG. 2.

Referring to FIGS. 7, 8, and 9, the semiconductor device 200 may include a plurality of bit lines BL′, wherein the plurality of bit lines BL′ may include a plurality of first bit lines BL1 and a plurality of second bit lines BL2.

In some embodiments, the plurality of first bit lines BL1 may be spaced apart from each other in the first horizontal direction (e.g., X direction), may each extend in the second horizontal direction (e.g., Y direction), and may be arranged such that a shield metal layer SS partially or completely fills spaces between the plurality of first bit lines BL1. Some portions of the shield metal layer SS may partially or completely fill the spaces between the plurality of first bit lines BL1 and extend in the second horizontal direction (e.g., Y direction), and the other portions of the shield metal layer SS may be arranged between the bottom surfaces of the plurality of first bit lines BL1 and the top surface of the cell wiring structure 160. The sidewalls and the bottom surface of the first bit line BL1 may be covered by or located on the first bit line insulating layer 152 and the second bit line insulating layer 154, wherein the first bit line insulating layer 152 and the second bit line insulating layer 154 may be arranged between the sidewalls of the first bit line BL1 and the shield metal layer SS and between the bottom surface of the first bit line BL1 and the shield metal layer SS.

In some embodiments, the plurality of second bit lines BL2 may each include a portion extending from the first bit line BL1 to partially or completely fill a recess RS1 on the channel layer AP. The recess RS1 may be formed by removing a portion of the channel layer AP during the manufacturing process. The plurality of second bit lines BL2 may be spaced apart from each other in the first horizontal direction (e.g., X direction) and the second horizontal direction (e.g., Y direction). The plurality of second bit lines BL2 may each be arranged between the channel layer AP and the first bit line BL1 and between the plurality of mold structures 130 facing each other. One end of each of the plurality of second bit lines BL2 may be in contact with the channel layer AP, and the other end of each of the plurality of second bit lines BL2 may be in contact with the first bit line BL1.

The bit line contact 156 may be arranged between the bottom surface of the first bit line BL1 and the cell wiring layer 162. The sidewall of the bit line contact 156 may be surrounded by the bit line contact spacer 158. The bit line contact 156 may be electrically insulated from the shield metal layer SS by the bit line contact spacer 158.

The plurality of mold structures 130 and the plurality of cell transistors CTR may be arranged on top surfaces of the plurality of bit lines BL′. For example, the plurality of mold structures 130 may each extend in the first horizontal direction (e.g., X direction), and the plurality of cell transistors CTR may be disposed on both sidewalls of each mold structure 130.

Each of the plurality of mold structures 130 may include the first mold layer 132, the second mold layer 134, and the third mold layer 136, each arranged in the vertical direction (e.g., Z direction). For example, the third mold layer 136 may be arranged on the bit line BL′ and the first bit line insulating layer 152. For example, the third mold layer 136 may be in contact with (i.e., on) the bit line BL′ and on the first bit line insulating layer 152. In some embodiments, the bottom surface of the third mold layer 136 may be in contact with the first bit line BL1. At least a portion of the sidewall of the third mold layer 136 may be in contact with a portion of the second bit line BL2. The second mold layer 134 may be disposed on the third mold layer 136, and the first mold layer 132 may be disposed on the second mold layer 134.

In some embodiments, the cell transistor CTR may include a channel layer AP, a gate insulating layer GI, and a word line WL, which are sequentially arranged on the sidewall of the mold structure 130.

In some embodiments, the channel layer AP may extend in the vertical direction (e.g., Z direction) and may have a top surface arranged on the same plane (i.e., coplanar with) as the top surface of the mold structure 130 and a bottom surface arranged on the different plane (i.e., non-coplanar with) from the bottom surface of the mold structure 130. The bottom surface of the channel layer AP and the bottom surface of the mold structure 130 may each be in contact with the top surface of the bit line BL′. For example, the bottom surface of the channel layer AP may be in contact with the top surface of the second bit line BL2 and the bottom surface of the mold structure 130 may be in contact with the top surface of the first bit line BL1.

The gate insulating layer GI may be disposed on the sidewall of the channel layer AP and the sidewall of the second bit line BL2. The word line WL may be disposed on the sidewall of the gate insulating layer GI. The top surface of the word line WL may be covered by the gate insulating layer GI and the bottom surface of the word line WL may be arranged at a higher vertical level (i.e., height) than the bottom surface of the channel layer AP. The insulating liner 142 and the buried insulating layer 144 may be arranged between two adjacent word lines WL.

Each of a plurality of landing pads LP and an oxide semiconductor layer LPO on or covering sidewalls and a bottom surface of each of the plurality of landing pads LP may be disposed on the plurality of cell transistors CTR. Each of the plurality of landing pads LP and the oxide semiconductor layer LPO may be configured similarly as described above with reference to FIGS. 1, 2, 3, 4, and 5. An insulating layer 176 may be arranged partially or completely around the oxide semiconductor layer LPO and the cell capacitor CAP.

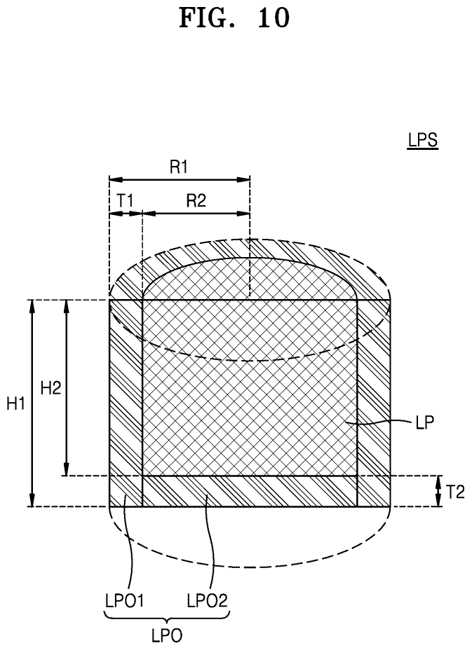

FIG. 10 is a schematic diagram of a landing pad structure LPS according to some embodiments.

Referring to FIG. 10, the landing pad structure LPS may include a landing pad LP and an oxide semiconductor layer LPO on or covering the sidewalls and the bottom surface of the landing pad LP. The landing pad structure LPS may have a first height H1 and a first radius R1, and the landing pad LP may have a second height H2 and a second radius R2.

In this case, a first thickness T1 of a first oxide semiconductor layer LPO1 may be a result value obtained by subtracting the second radius R2 from the first radius R1, and a second thickness T2 of a second oxide semiconductor layer LPO2 may be a result value obtained by subtracting the second height H2 from the first height H1. Each of the first thickness T1 and the second thickness T2 may be relatively (i.e., approximately) constant.

The contact area between the landing pad LP and the oxide semiconductor layer LPO may be obtained from Equation 1 below:

$${A}_{c} = π {( {R}_{2} )}^{2} + 2 π {R}_{2} \times {H}_{2} \qquad [ Equation 1 ]$$

In Equation 1, A_{c} is the contact area between the landing pad LP and the oxide semiconductor layer LPO, R₂ is the second radius R2, and H₂ is the second height H2.

According to a comparative example, since the landing pad is directly electrically connected to the channel layer without an oxide semiconductor layer electrically connecting the landing pad to the channel layer and the contact area between the landing pad and the channel layer is relatively small (e.g., the contact area is within about 80 square nanometers to 100 square nanometers), the contact resistance between the landing pad and the channel layer may be relatively large.

According to some embodiments, as the oxide semiconductor layer LPO electrically connecting the landing pad LP to the channel layer AP is introduced and the oxide semiconductor layer LPO partially or completely surrounds the sidewalls and the bottom surface of the landing pad LP to increase the contact area between the oxide semiconductor layer LPO and the landing pad LP (e.g., the contact area is within about 500 nanometers to about 550 nanometers), the contact resistance between the landing pad LP and the channel layer AP may be reduced by the oxide semiconductor layer LPO, thereby providing the semiconductor device with relatively improved electrical characteristics.

For example, it was confirmed that the semiconductor device according to the comparative example has a contact resistance of 5.0×10⁻⁴ Ωcm², while the semiconductor device according to some embodiments had a contact resistance of 6.3×10⁻⁷ Ωcm², indicating that the contact resistance was reduced by approximately 790 times to 800 times.

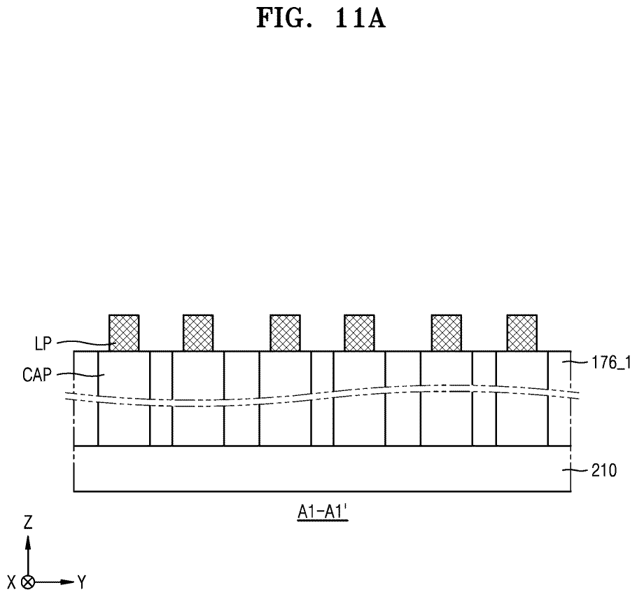

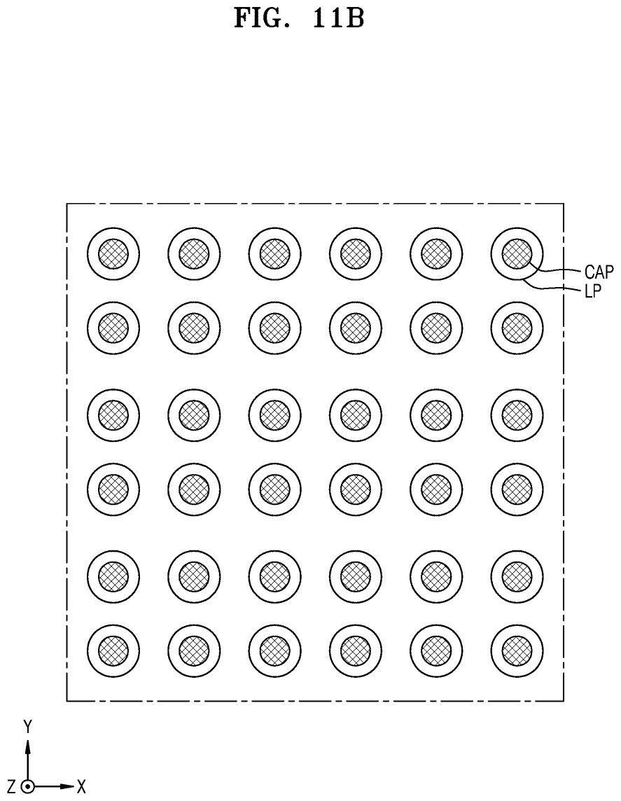

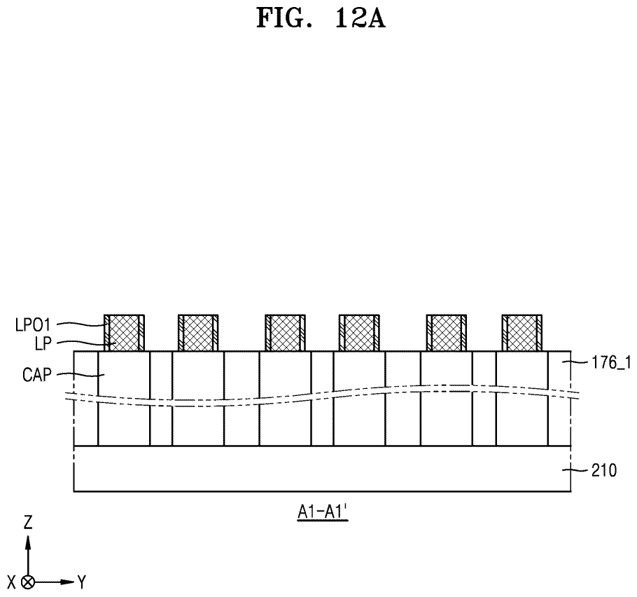

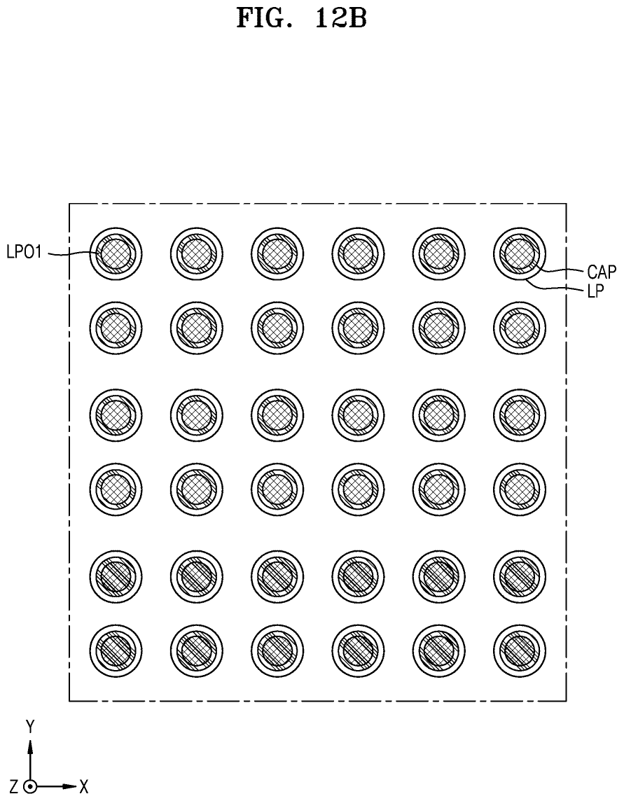

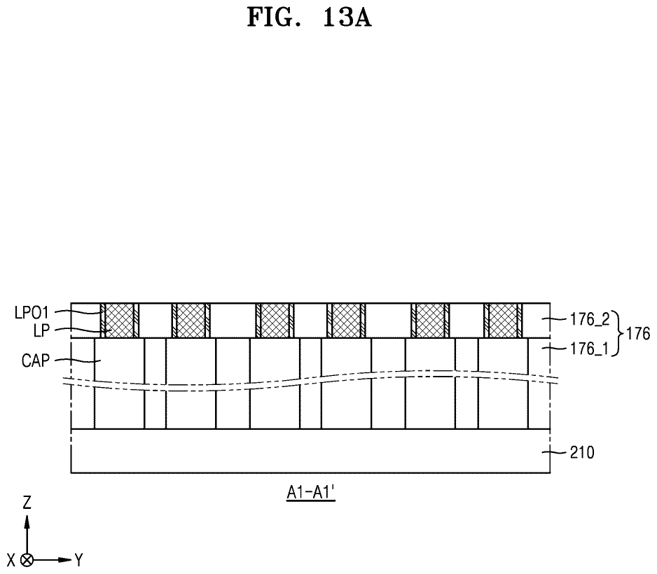

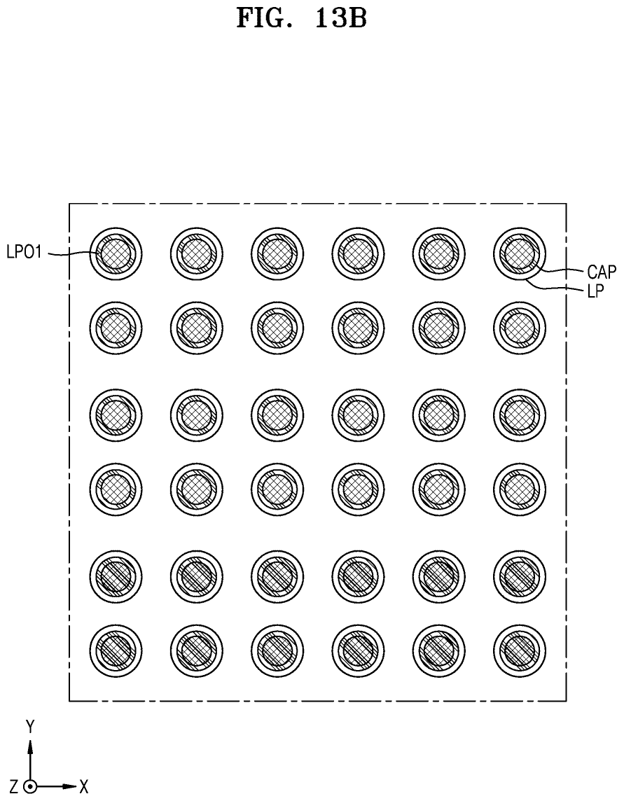

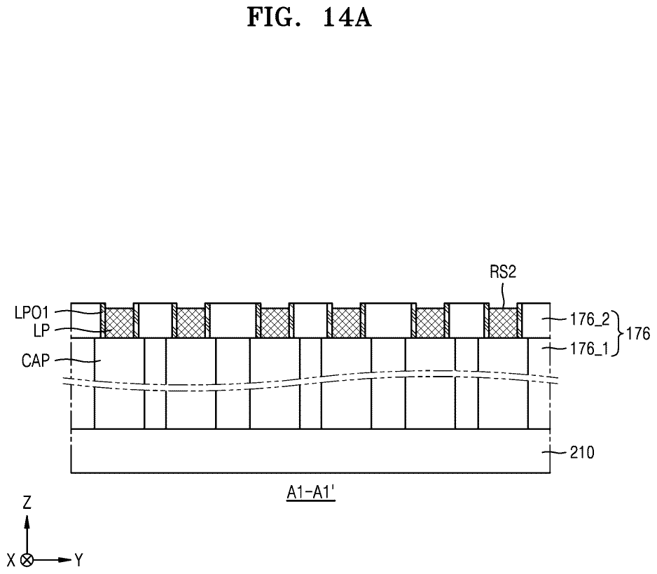

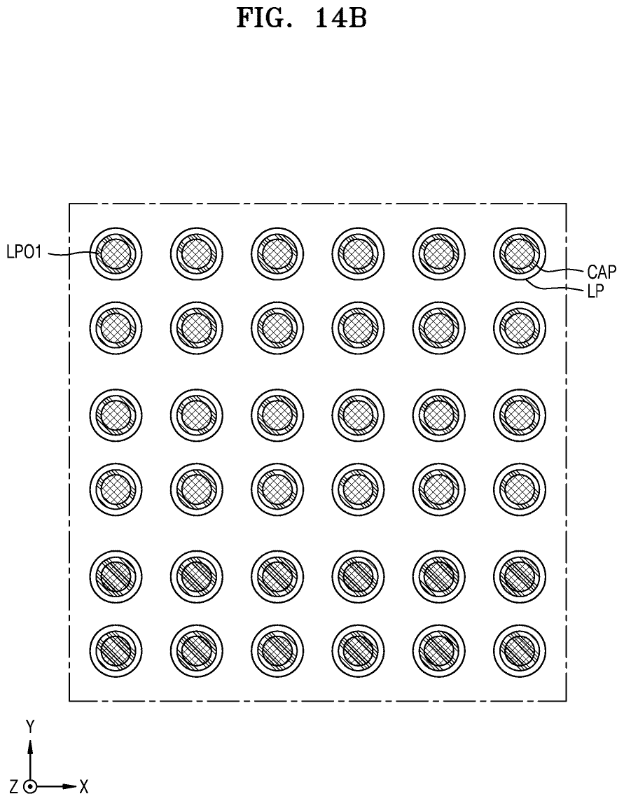

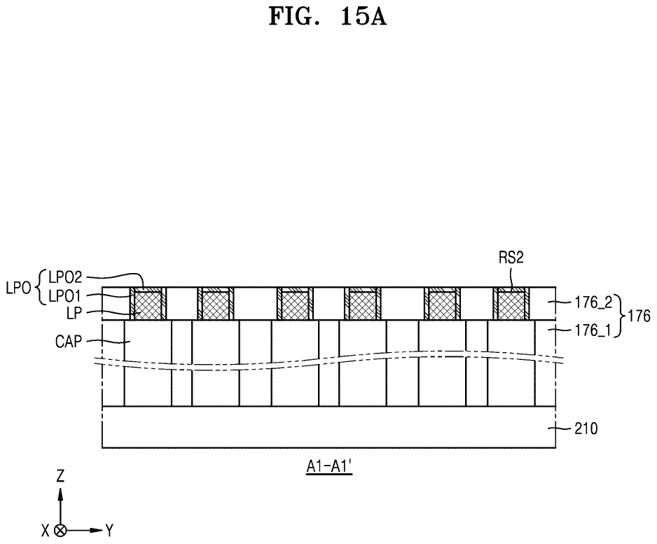

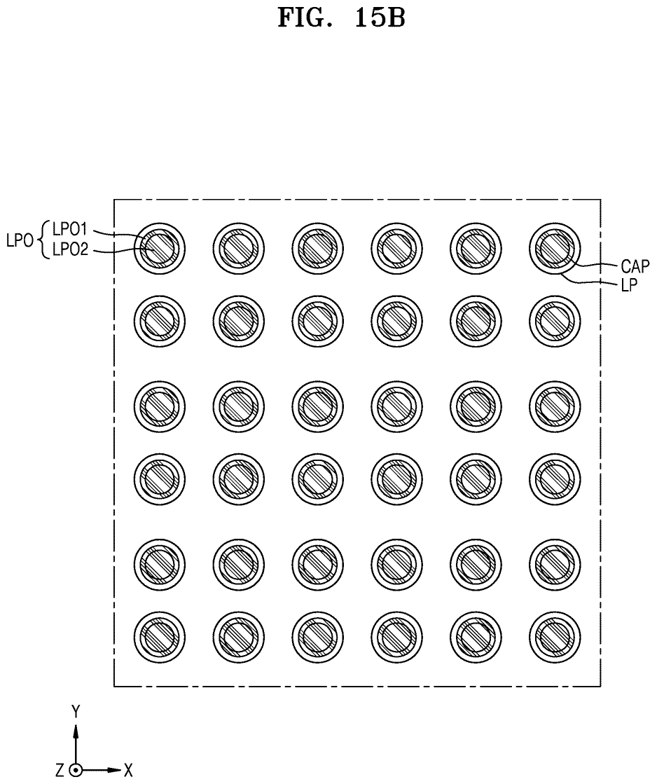

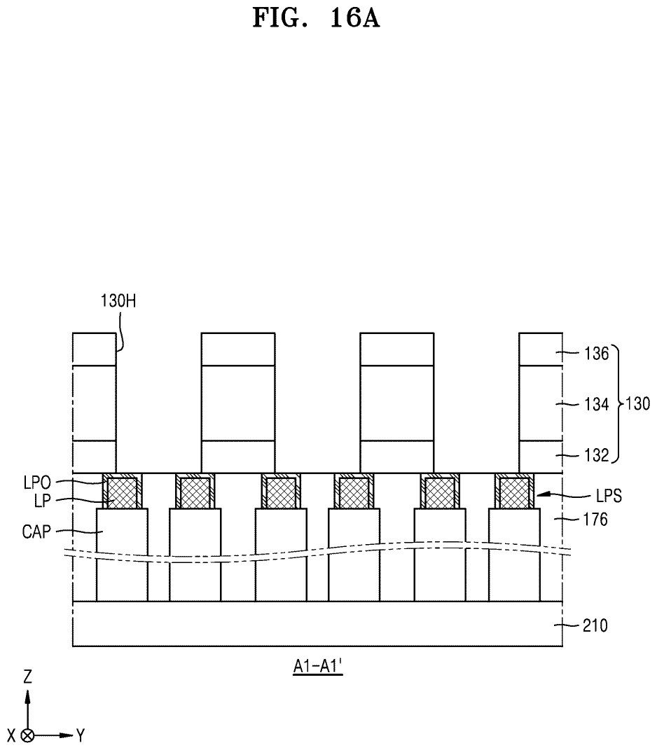

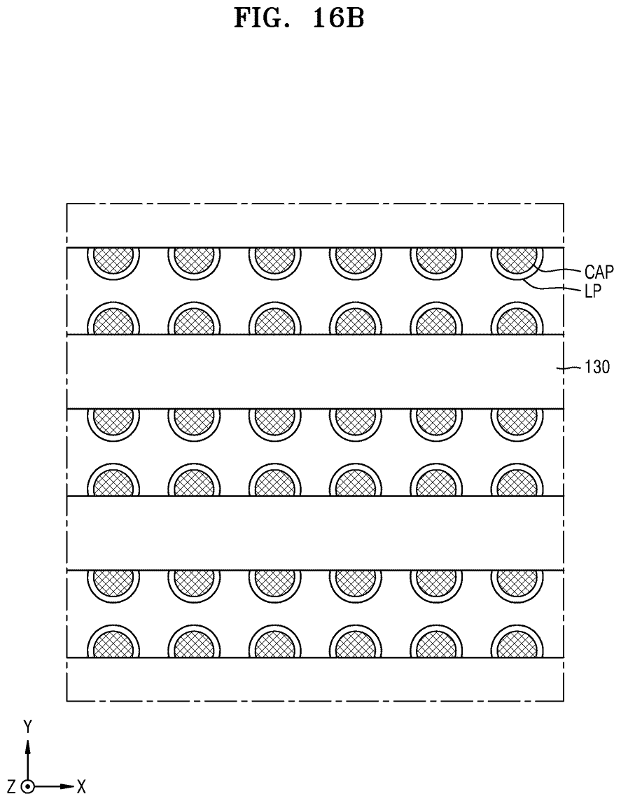

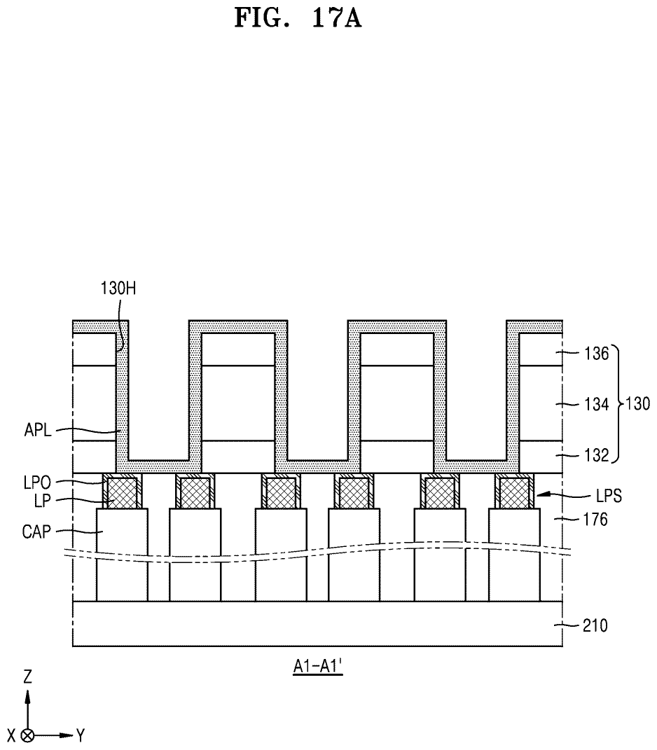

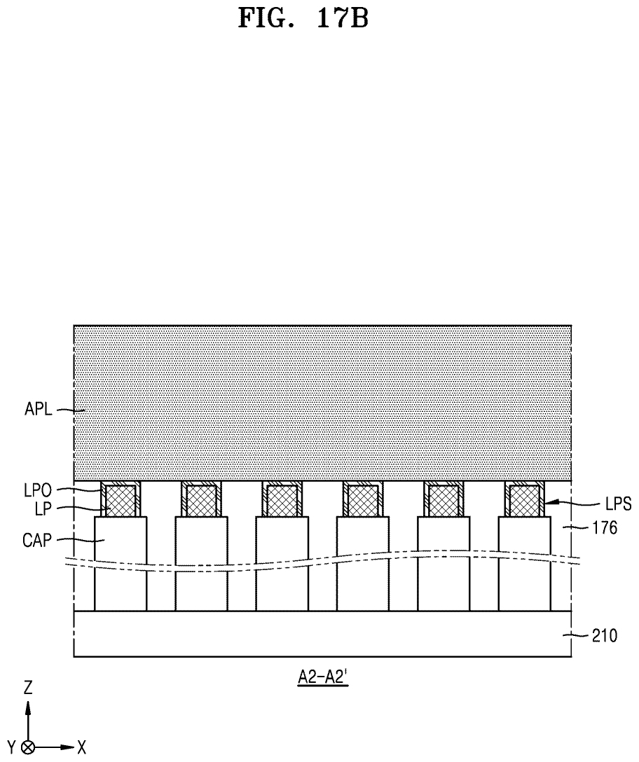

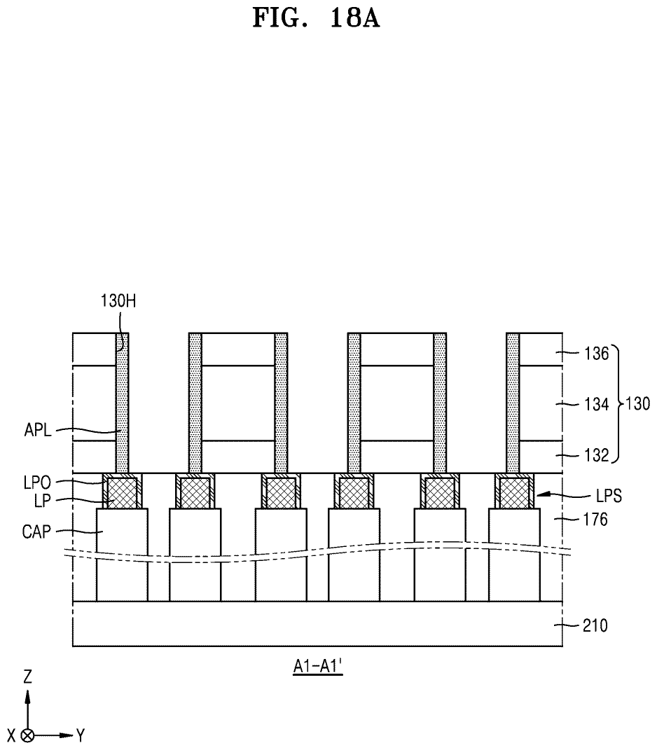

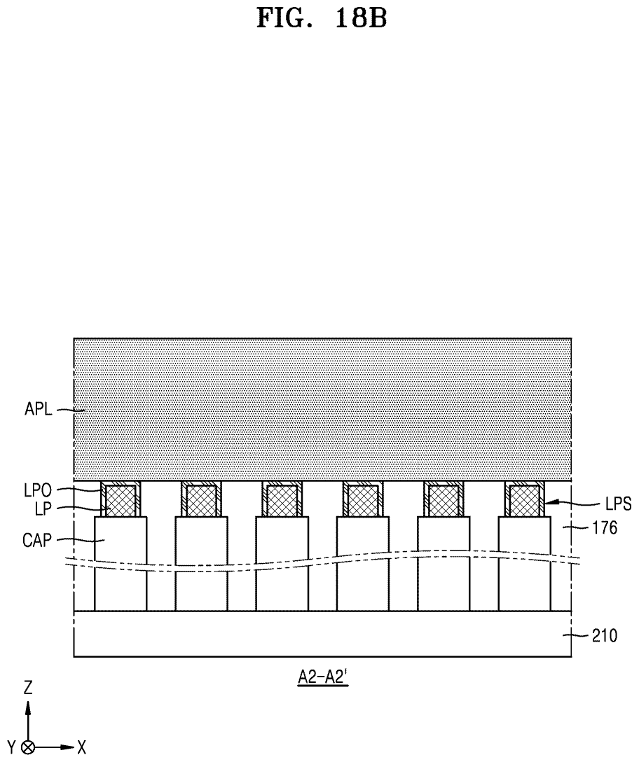

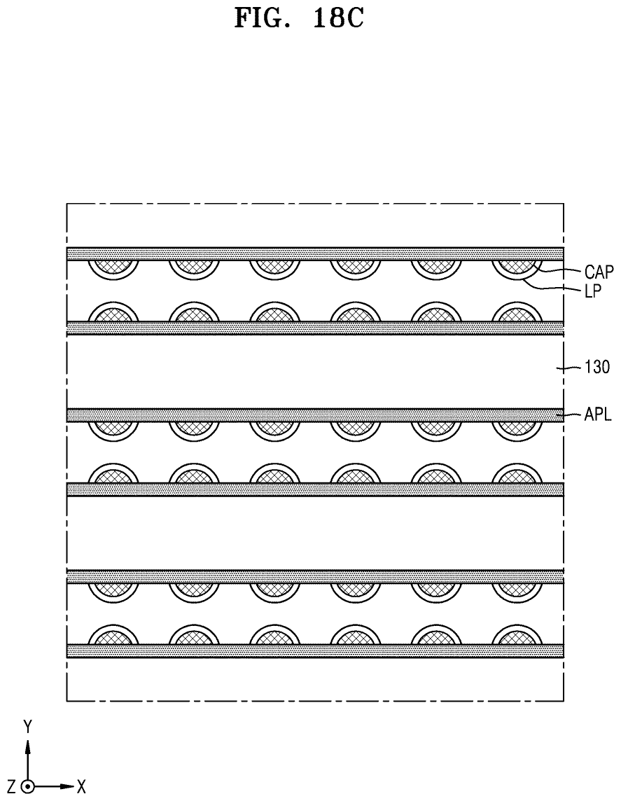

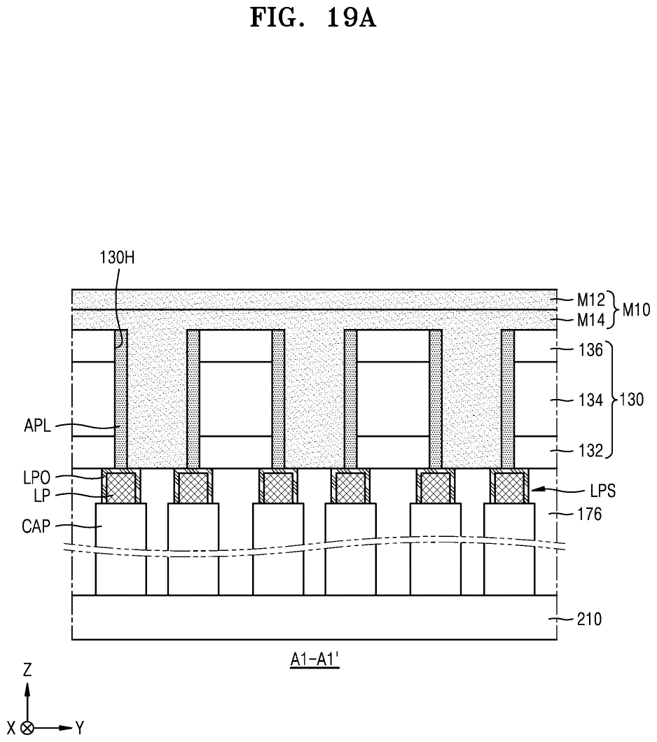

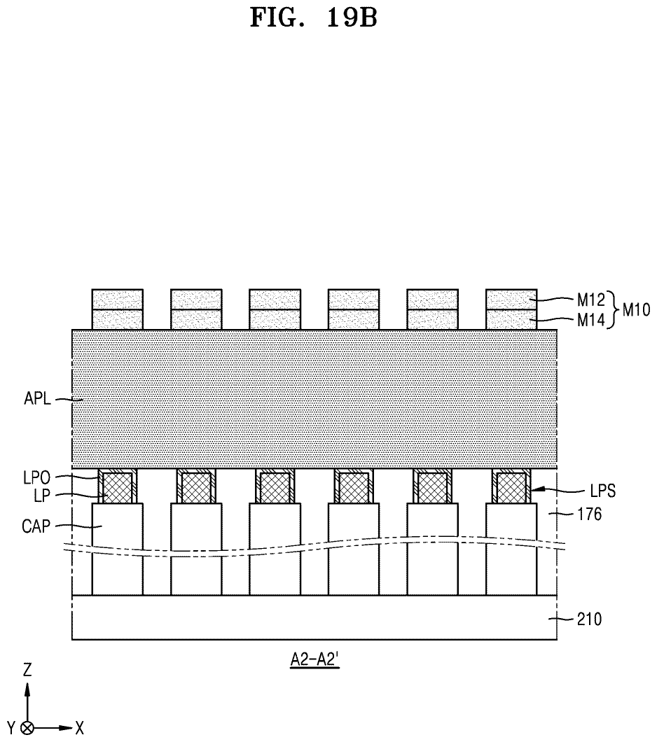

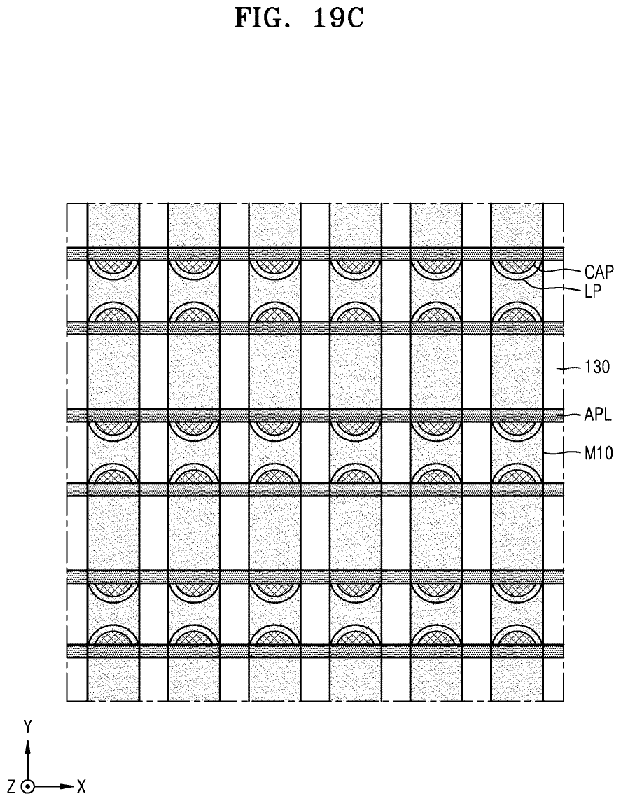

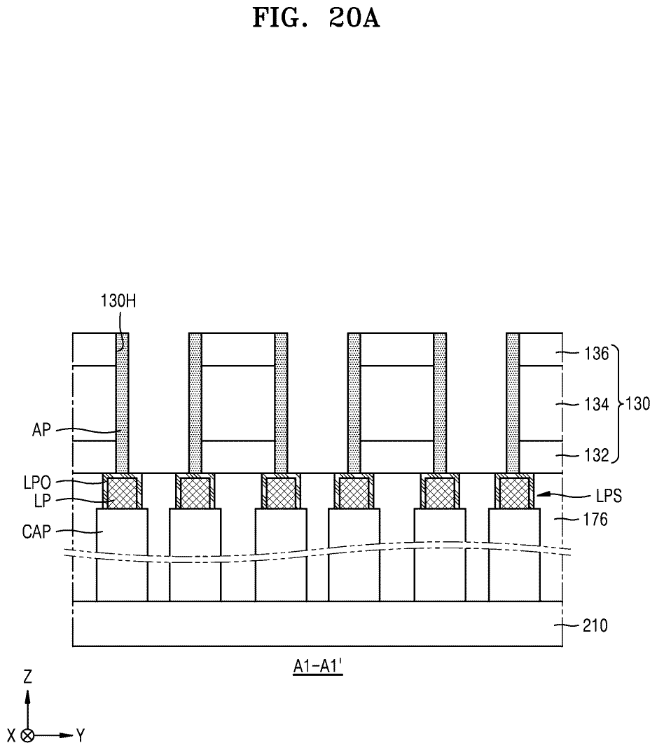

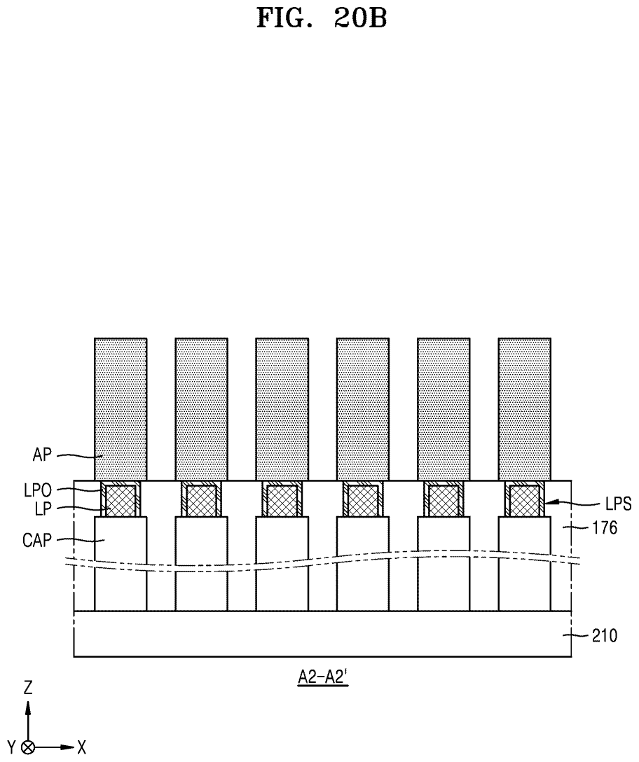

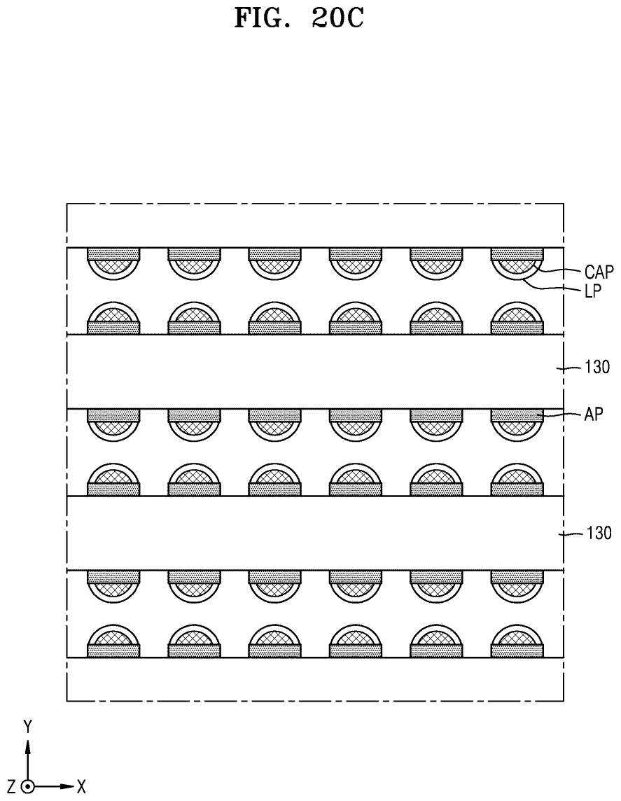

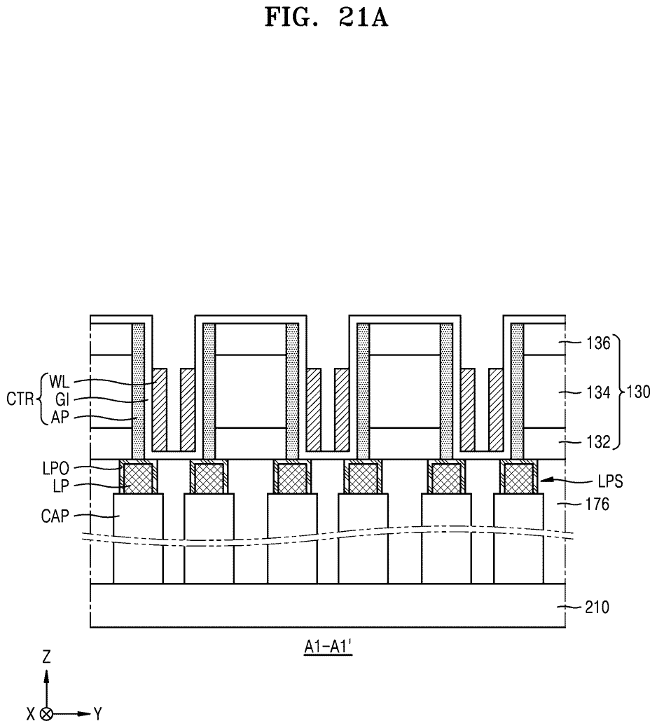

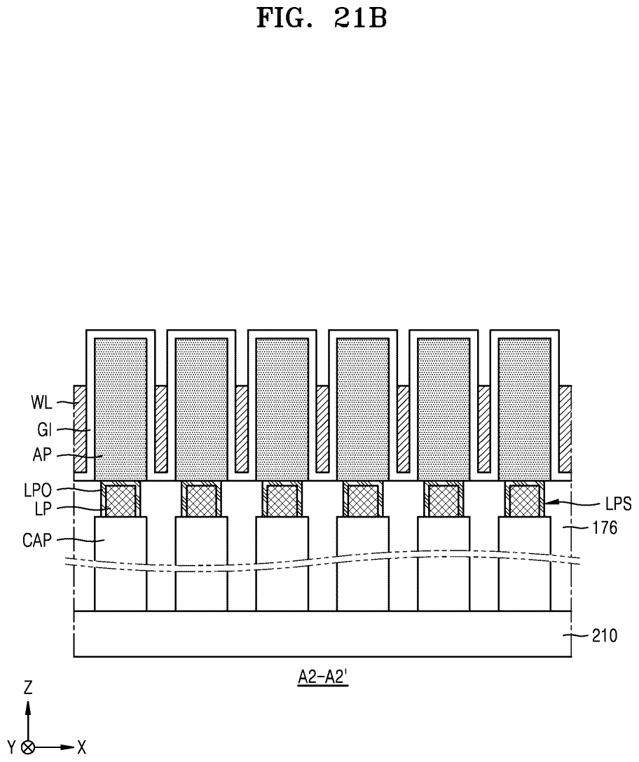

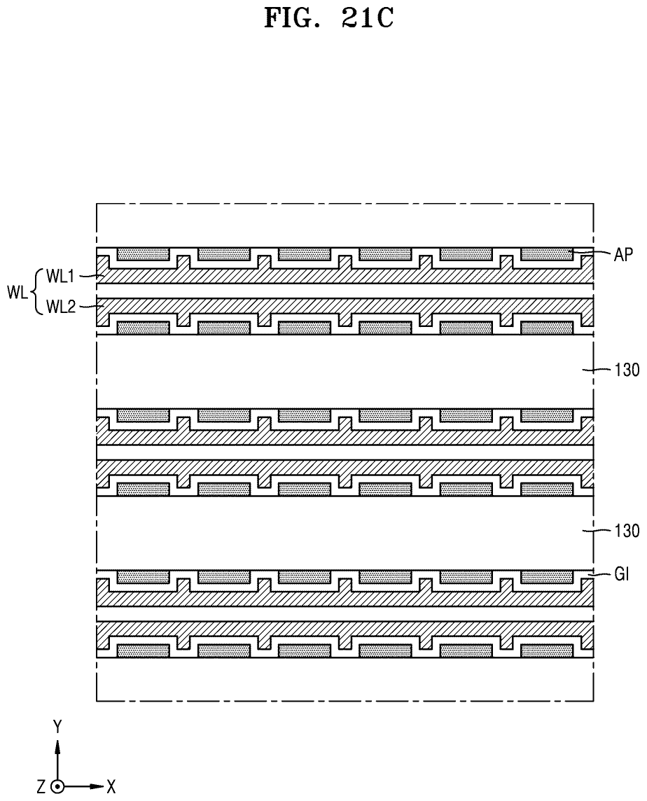

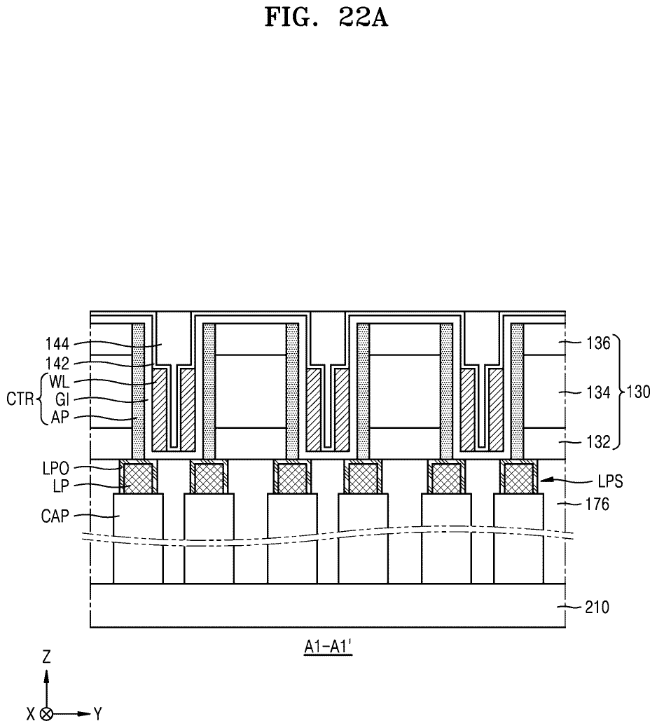

FIGS. 11A, 11B, 12A, 12B, 13A, 13B, 14A, 14B, 15A, 15B, 16A, 16B, 17A, 17B, 18A, 18B, 18C, 19A, 19B, 19C, 20A, 20B, 20C, 21A, 21B, 21C, 22A, 22B, 23A, 23B, 24A, 24B, 25A, 25B, 25C, 26A, 26B, 26C, 27, 28 and 29 are diagrams sequentially illustrating a method of manufacturing a semiconductor device, according to some embodiments.

Referring to FIGS. 11A and 11B, a plurality of cell capacitors CAP and a first insulating layer 176_1 on or surrounding sidewalls of the plurality of cell capacitors CAP may be formed on a carrier substrate 210, and a plurality of landing pads LP may be formed on the plurality of cell capacitors CAP, respectively.

In some embodiments, as shown in FIG. 11B, the plurality of cell capacitors CAP and the plurality of landing pads LP may be arranged in a matrix shape. In some embodiments, the plurality of cell capacitors CAP and the plurality of landing pads LP may be arranged in a hexagon.

To form the plurality of landing pads LP, a landing pad conductive layer (not shown) conformally on or covering top surfaces of the plurality of cell capacitors CAP and the first insulating layer 176_1 may be formed first, and then the plurality of landing pads LP may be formed by patterning the landing pad conductive layer. The landing pad conductive layer may include Ti, TiN, Ta, TaN, W, WN, TiSiN, WSiN, polysilicon, and/or combinations thereof.

Referring to FIGS. 12A and 12B, an oxide semiconductor material layer (not shown) may be formed to conformally cover sidewalls and top surfaces of the plurality of landing pads LP, exposed portions of the top surfaces of the plurality of cell capacitors CAP, and a top surface of the first insulating layer 176_1.

Thereafter, an etch-back process may be performed on the top surfaces of the plurality of landing pads LP, the exposed portions of the top surfaces of the plurality of cell capacitors CAP, and the top surface of the first insulating layer 176_1 to remove portions of the oxide semiconductor material layer on or covering the top surfaces of the plurality of landing pads LP, the exposed portions of the top surfaces of the plurality of cell capacitors CAP, and the top surface of the first insulating layer 176_1. The other portions of the oxide semiconductor material layer on or covering the sidewalls of the plurality of land pads LP may remain to form the first oxide semiconductor layers LPO1 on or covering the sidewalls of the plurality of landing pads LP. The etch-back process may include a wet and/or dry etching process.

The oxide semiconductor material layer may include at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), and/or zirconium zinc tin oxide (Zr_{X}Zn_{y}Sn_{z}O).

After the oxide semiconductor material layer is deposited, the ion implantation process or the like for doping n-type impurity ions into the oxide semiconductor material layer may be further performed.

Referring to FIGS. 13A and 13B, a second insulating layer 176_2 may be formed to partially or completely cover the sidewalls of the first oxide semiconductor layers LPO1, the exposed portions of the top surfaces of the plurality of cell capacitors CAP, and the top surface of the first insulating layer 176_1. For example, after a silicon nitride film on or covering the sidewalls of the first oxide semiconductor layers LPO1, the exposed portions of the top surfaces of the plurality of cell capacitors CAP, and the top surface of the first insulating layer 176_1 is deposited, the top surface of the silicon nitride film may be planarized by chemical mechanical polishing (CMP) to form the second insulating layer 176_2.

After the silicon nitride film is deposited, hydrogen plasma treatment may be further performed on the surface of the silicon nitration film to increase a hydrogen content in the silicon nitride film.

Referring to FIGS. 14A and 14B, a metal etch-back process may be performed on the top surface of the landing pad LP to remove a portion of the landing pad LP to form a landing pad recess RS2. The metal etch-back process may include a wet and/or dry etching process. The metal etch-back process may be performed for a certain period of time in consideration of the thickness of a second oxide semiconductor layer to be formed in the landing pad recess RS2 and may be performed so that a portion of the landing pad LP is removed and the other portion remains.

Referring to FIGS. 15A and 15B, a second oxide semiconductor layer LPO2 may be formed in the landing pad recess RS2. To form the second oxide semiconductor layer LPO2, the oxide semiconductor material layer on or covering a top surface of the second insulating layer 176_2 and conformally on or covering sidewalls and a bottom surface of the landing pad recess RS2 may be formed to fill the landing pad recess RS2. Subsequently, the CMP process may be performed on the top surface of the oxide semiconductor material layer to remove a portion of the oxide semiconductor material layer that does not fill the landing pad recess RS2, while leaving the other portion of the oxide semiconducting material layer that partially or completely fills the landing pad recess RS2.

The oxide semiconductor material layer may include at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), and/or zirconium zinc tin oxide (Zr_{X}Zn_{y}Sn_{z}O).

After the oxide semiconductor material layer is deposited, the ion implantation process or the like for doping n-type impurity ions into the oxide semiconductor material layer may be further performed.

In some embodiments, after the second oxide semiconductor layer LPO2 is formed, a surface treatment process using plasma may be further performed on the first oxide semiconductor layers LPO1 and the second oxide semiconductor layer LPO2. For example, a surface treatment process using fluorine (F), boron (B), or argon (Ar), such as an ion bombardment process, may be further performed. The surface treatment process may include a process performed for increasing or imparting conductivity to the first oxide semiconductor layers LPO1 and the second oxide semiconductor layer LPO2.

Since the first oxide semiconductor layers LPO1 and the second oxide semiconductor layer LPO2 are each formed through separate manufacturing processes in time series, the first oxide semiconductor layers LPO1 and the second oxide semiconductor layer LPO2 may be independently formed. In some embodiments, the first oxide semiconductor layers LPO1 and the second oxide semiconductor layer LPO2 may include the same material. In some embodiments, the first oxide semiconductor layers LPO1 and the second oxide semiconductor layer LPO2 may include different materials. In some embodiments, the first oxide semiconductor layers LPO1 and the second oxide semiconductor layer LPO2 may be formed with same thicknesses. In some embodiments, the first oxide semiconductor layers LPO1 and the second oxide semiconductor layer LPO2 may be formed with different thicknesses.

Referring to FIGS. 16A and 16B, a mold structure 130 extending in the first horizontal direction (e.g., X direction) may be formed on the oxide semiconductor layer LPO (i.e., the first oxide semiconductor layers LPO1 and the second oxide semiconductor layer LPO2 in FIGS. 15A and 15B) and the insulating layer 176 (i.e., the first insulating layer 176_1 and the second insulating layer 176_2 in FIGS. 15A and 15B). The mold structure 130 may include a first mold layer 132, a second mold layer 134, and a third mold layer 136, which are sequentially disposed on the oxide semiconductor layer LPO and the insulating layer 176. The mold structure 130 may include a sidewall 130H extending in the first horizontal direction (e.g., X direction).

In some embodiments, the width of the mold structure 130 in the second horizontal direction (e.g., Y direction) may be determined so that two oxide semiconductor layers LPO each partially or completely on or covering the two landing pads LP in the second horizontal direction (e.g., Y direction) are exposed between two adjacent mold structures 130.

Referring to FIGS. 17A and 17B, a preliminary channel layer APL may be formed on the sidewalls 130H of the mold structure 130. The preliminary channel layer APL may be conformally disposed on the sidewalls 130H and the top surface of the mold structure 130, and on the top surface of the oxide semiconductor layer LPO and the top surface of the insulating layer 176. For example, the thickness of the preliminary channel layer APL disposed on the sidewalls 130H of the mold structure 130 may be the same or similar to that of the preliminary channel layer APL disposed on the top surface of the mold structure 130, and on the top surface of the oxide semiconductor layer LPO and the top surface of the insulating layer 176.

Referring to FIGS. 18A, 18B, and 18C, an anisotropic etching process or an etch-back process may be performed on the preliminary channel layer APL to remove portions of the preliminary channel layer APL disposed on the top surface of the mold structure 130 and on the top surface of the insulating layer 176, thereby leaving only the other portions of the preliminary channel layer APL disposed on the sidewalls 130H of the mold structure 130.

The top surface of the mold structure 130 (e.g., the top surface of the third mold layer 136) may be exposed again by the anisotropic etching process or the etch-back process. The top surface of the mold structure 130 (e.g., the top surfaces of the third mold layer 136) may be arranged at the same level (i.e., height) as the top surface of the preliminary channel layer APL. In addition, as shown in FIG. 18A, the bottom surface of the preliminary channel layer APL may be on or in contact with the top surface of the oxide semiconductor layer LPO. The preliminary channel layer APL may extend in the first horizontal direction (e.g., X direction) on the sidewalls 130H of the mold structure 130.

Referring to FIGS. 19A, 19B, and 19C, a mask pattern M10 extending in the second horizontal direction (e.g., Y direction) may be formed on the mold structure 130 and the preliminary channel layer APL.

In some embodiments, the mask pattern M10 may include a lower mask layer M14 partially or completely filling the space between two adjacent preliminary channel layers APL and an upper mask layer M12 on the lower mask layer M14. For example, the lower mask layer M14 may include a silicon-on-hardmask and the upper mask layer M12 may include silicon oxynitride.

Referring to FIGS. 20A, 20B, and 20C, portions of the preliminary channel layer APL not covered by the mask pattern M10 may be removed. The other portions of the preliminary channel layer APL on or covered by the mask pattern M10 may remain without being removed, and may be referred to as channel layers AP. The channel layers AP may be spaced apart from each other in the first horizontal direction (e.g., X direction) between two adjacent mold structures 130, wherein one channel layer AP may be disposed on one landing pad LP.

Referring to FIGS. 21A, 21B, and 21C, a gate insulating layer GI and word lines WL may be formed on the sidewalls of the channel layer AP.

In some embodiments, the gate insulating layer GI may be conformally formed on the top surface of the mold structure 130, on the sidewalls of the channel layer AP, and on the top surface the insulating layer 176.

Thereafter, the word lines WL may be formed on the sidewalls of the channel layer AP with the gate insulating layer GI arranged therebetween. In the process of forming the word lines WL, an anisotropic etching process or a recess process may be performed on the word lines WL after the word lines WL are conformally formed on the top surface and sidewalls of the gate insulating layer GI, thereby leaving word lines WL only between two adjacent mold structures 130 (e.g., only on the sidewalls of the gate insulating layer GI).

As shown in FIG. 21C, between two adjacent mold structures 130, one word line WL may be disposed on the sidewall of one of the two mold structures 130 and the other word line WL is disposed on the sidewall of the other of the two mold structures 130.

Referring to FIGS. 22A and 22B, an insulating liner 142 and a buried insulating layer 144 may be sequentially formed on the word lines WL.

Referring to FIGS. 23A and 23B, a portion of the insulating liner 142 and a portion of the gate insulating layer GI, each disposed on the top surface of the mold structure 130, may be removed to expose the top surface of the mold structure 130 and the top surface of the channel layer AP again.

The process of removing the portion of the insulating liner 142 and the portion of the gate insulating layer GI may include a grinding or CMP process. After the grinding or CMP process, the top surface of the buried insulating layer 144, the top surface the channel layer AP, and the top surface of the mold structure 130 may be arranged on the same plane.

Referring to FIGS. 24A and 24B, an intermediate line layer BULp may be formed on the top surface of the buried insulating layer 144, the channel layer AP, and the mold structure 130.

In some embodiments, the intermediate line layer BULp may include the oxide semiconductor, and may include, for example, the same material as the material constituting the channel layer AP. In some embodiments, the intermediate line layer BULp may include the oxide semiconductor, and may include, for example, a different material from the material constituting the channel layer AP.

Thereafter, a bit line layer BLp may be formed on the intermediate line layer BULp. In some embodiments, the bit line layer BLp may include Ti, TiN, Ta, TaN, Mo, Ru, W, WN, Co, Ni, TiSi, TiSiN, WSi, WSiN, TaSi, TaSIN, RuTiN, CoSi, NiSi, polysilicon, and/or combinations thereof.

Referring to FIGS. 25A, 25B, and 25C, a plurality of mask patterns spaced apart from each other in the first horizontal direction (e.g., X direction) and extending in the second horizontal direction (e.g., Y direction) may be formed on the bit line layer BLp (see FIG. 24A), and the bit line layer BLp and the intermediate line layer BULp may be patterned using the plurality of mask patterns as etching masks to form a bit line BL and an intermediate line BUL.

In some embodiments, the bit line BL and the intermediate line BUL may be sequentially patterned during the same process, such that the sidewall of the bit line BL may be aligned with the sidewall of the intermediate line BUL.

As shown in FIG. 25A, the intermediate line BUL may have a line shape extending in the second horizontal direction (e.g., Y direction), a portion of the bottom surface of the intermediate line BUL may be on or in contact with the top surface of the channel layer AP, and the entire top surface of the intermediate line BUL may be on or in contact with the entire bottom surface of the bit line BL.

Referring to FIGS. 26A, 26B, and 26C, a first bit line insulating layer 152 and a second bit line insulating layer 154 may be sequentially formed on the intermediate line BUL and the bit line BL, and the shield metal layer SS may be formed on the second bit line insulating layer 154.

Referring to FIG. 27, a cell wiring structure 160 may be formed on the shield metal layer SS. The cell wiring structure 160 may include a cell wiring layer 162, a cell contact 164, and a cell insulating layer 166. In addition, a bit line contact 156 that connects (i.e., electrically and/or physically) the cell wiring layer 162 to the bit line BL may be further formed. The sidewalls of the bit line contact 156 may be surrounded by the bit line contact spacer 158. The bit line contact 156 may be electrically insulated from the shield metal layer SS by the bit line contact spacer 158.

A first bonding pad BP1 may be provided in the cell insulating layer 166 of the cell wiring structure 160. The first bonding pad BP1 may be electrically connected to the cell wiring layer 162. The top surface of the cell insulating layer 166 may be arranged on the same plane as (i.e., coplanar with) the top surface of the first bonding pad BP1, and the top surface of the cell insulating layer 166 may be referred to as a bonding interface BIF.

Referring to FIG. 28, an active region AC may be formed on the substrate 110, and a peripheral circuit transistor PTR may be formed on the active region AC. For example, the peripheral circuit transistor PTR may include a gate electrode PTG, a gate insulating layer PTI, and a source/drain region PTS.

Then, the peripheral circuit wiring 122 and the peripheral circuit contact 124 electrically connected to the substrate 110 and the peripheral circuit transistor PTR may be formed, and the peripheral circuit insulating layer 126 on or covering the peripheral circuit wiring 122 and the peripheral circuit contact 124 may be formed on the substrate 110. The peripheral circuit insulating layer 126 may be formed using an oxide film, a nitride film, a low dielectric film, and/or combinations thereof.

A second bonding pad BP2 may be provided in the peripheral circuit insulating layer 126. The second bonding pad BP2 may be electrically connected to the peripheral circuit wiring 122. The top surface of the peripheral circuit insulating layer 126 may be arranged on the same plane as the top surface of the second bonding pad BP2, and the top surface of the peripheral circuit insulating layer 126 may be referred to as the bonding interface BIF.

Referring to FIG. 29, the peripheral circuit area PCA and the cell array area MCA may be bonded to each other so that the cell wiring structure 160 and the peripheral circuit wiring structure 120 are partially or completely in contact with each other. In some embodiments, the first bonding pad BP1 and the second bonding pad BP2 may be partially or completely in contact with each other at the bonding interface BIF, and the cell insulating layer 166 and the peripheral circuit insulating layer 126 may be partially or completely in contact with each other at the bonding interface BIF.

The carrier substrate 210 may then be removed.

The semiconductor device 100 may be completed by performing the above-described process.

According to some embodiments, the peripheral circuit area PCA and the cell array area MCA may each be manufactured using a separate wafer and then bonded to each other using the bonding pad BP. When forming the cell array area MCA, the cell capacitor CAP may be first formed and then the cell transistor CTR may be formed. Thus, thermal damage to the cell transistor CTR may be prevented or minimized.

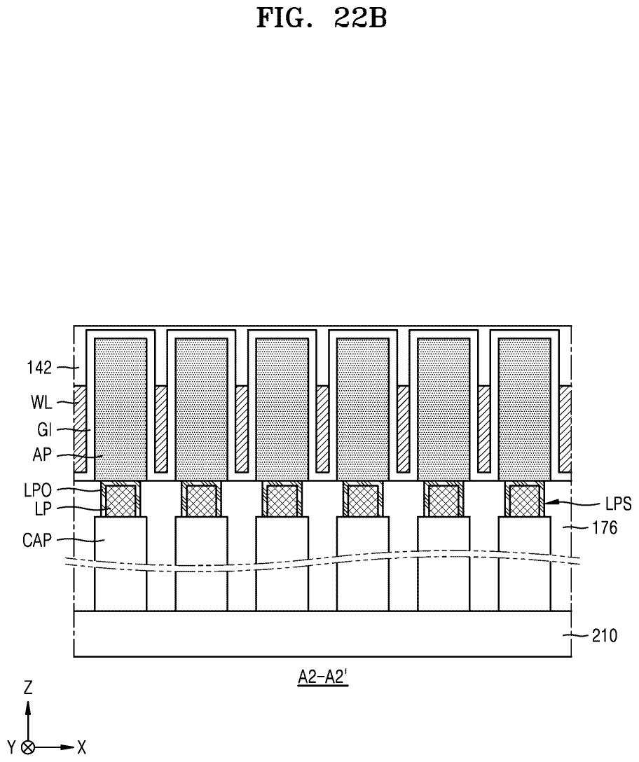

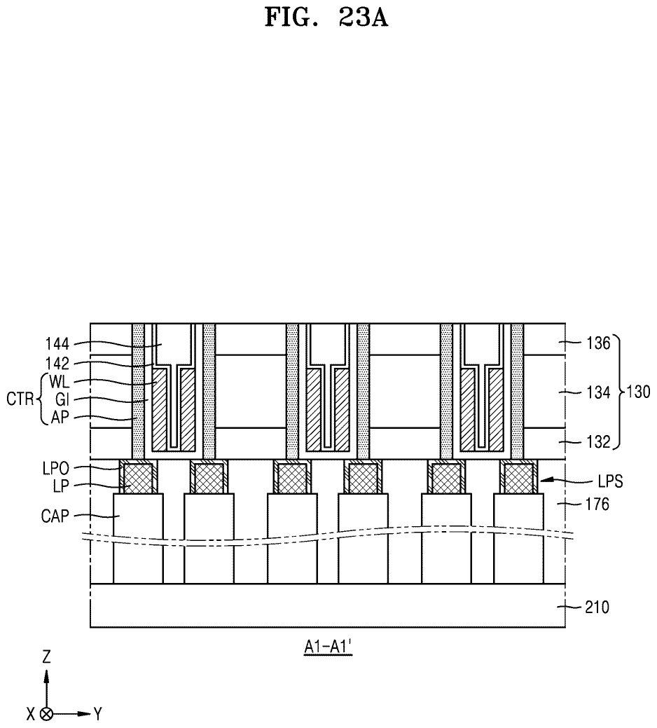

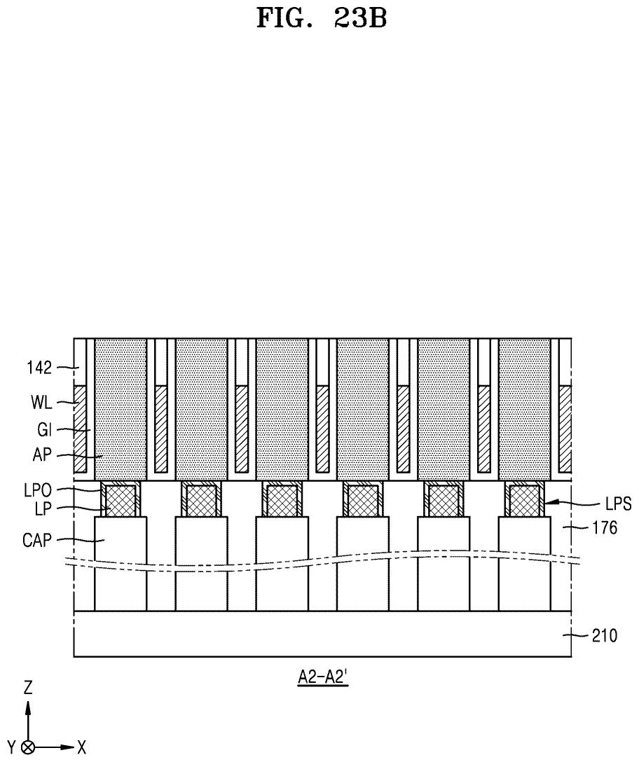

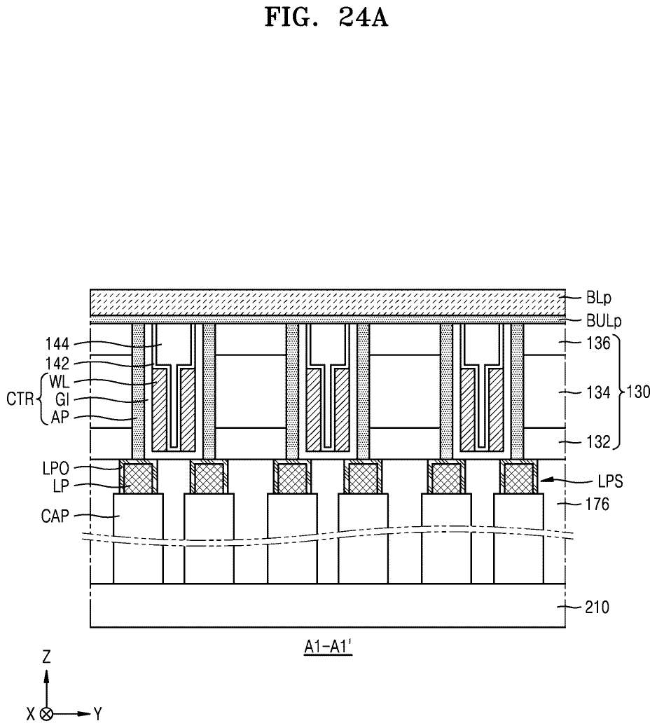

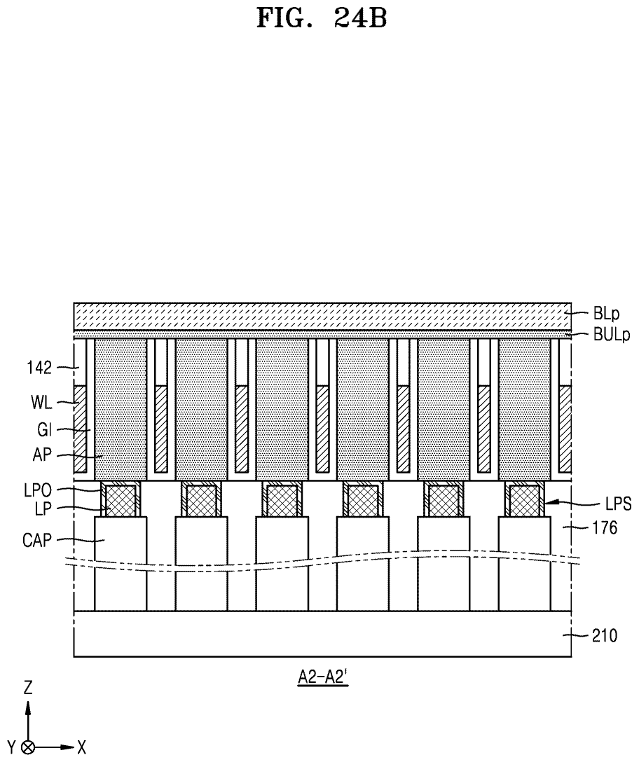

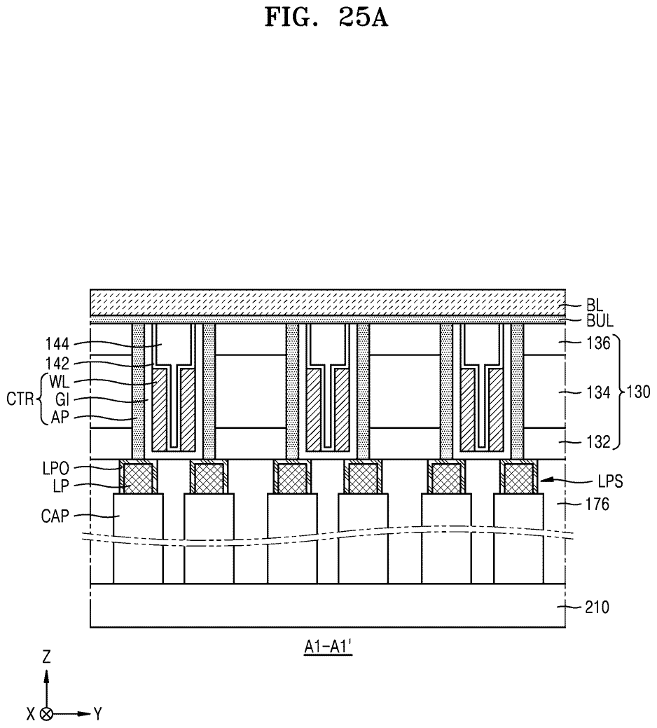

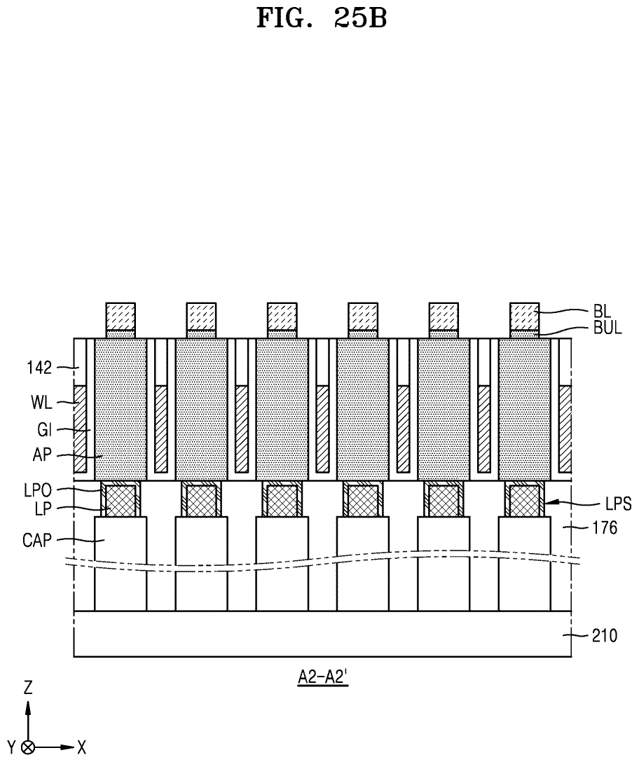

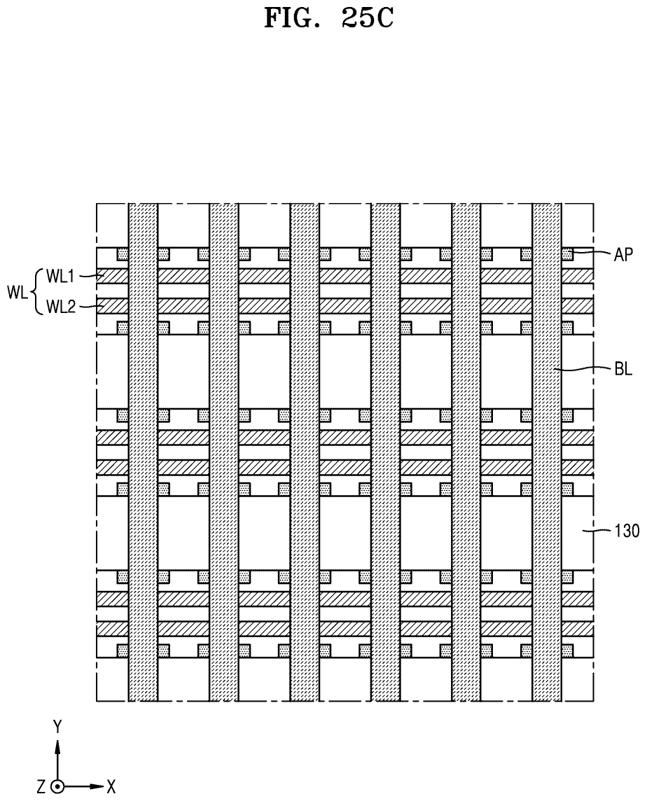

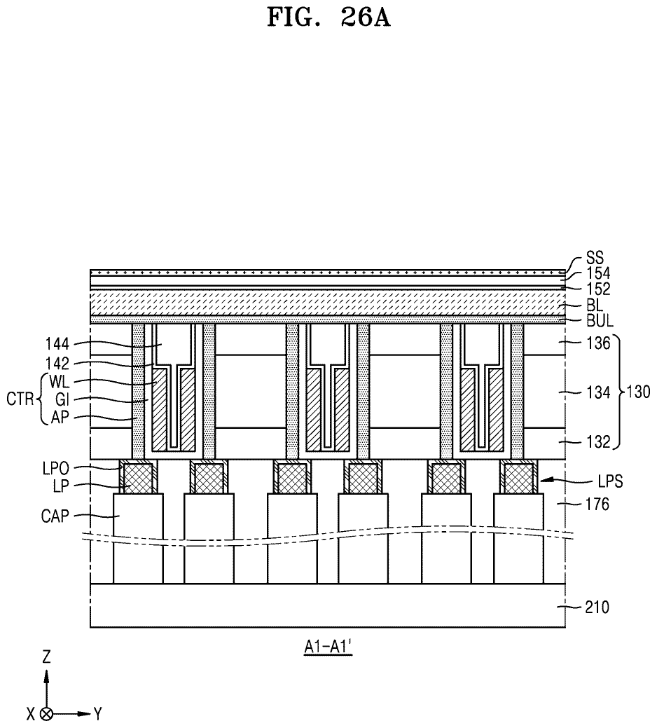

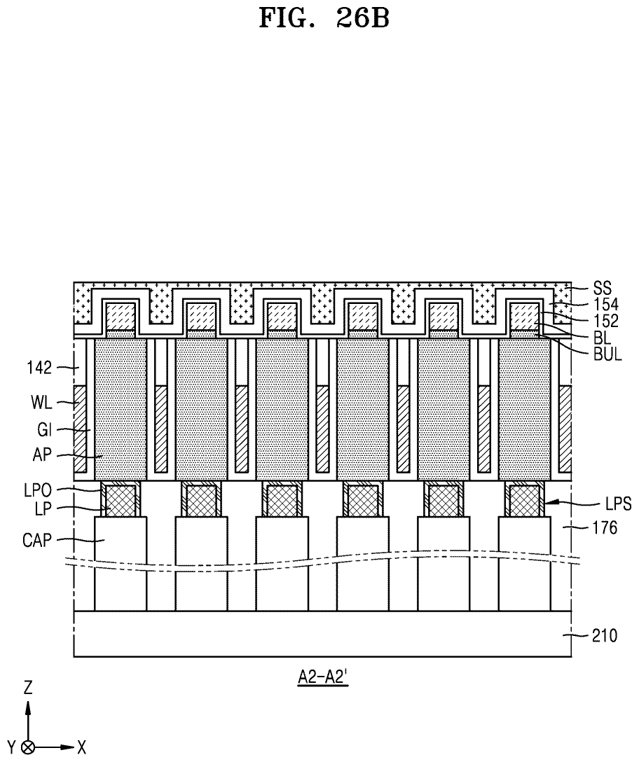

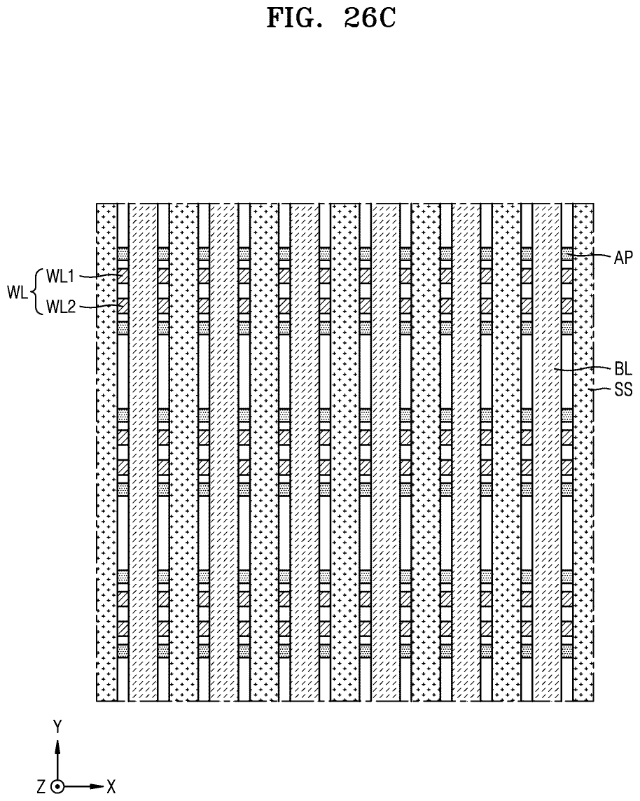

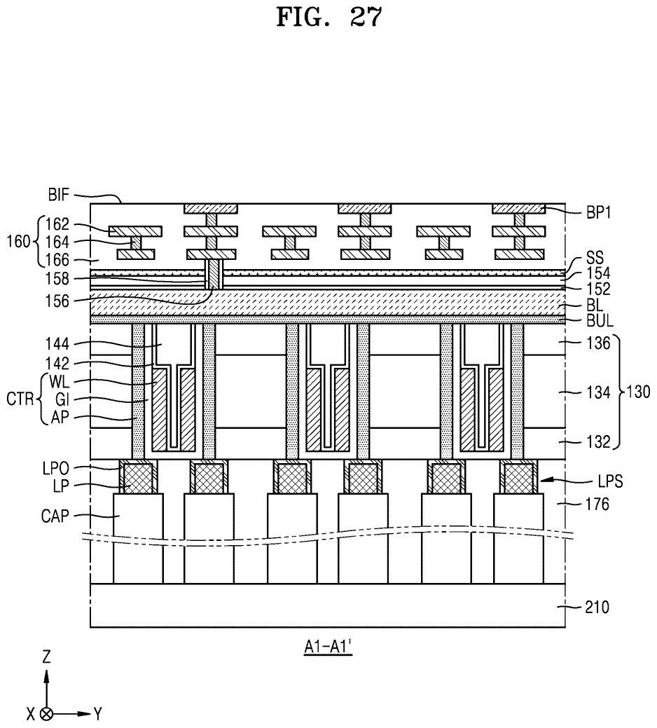

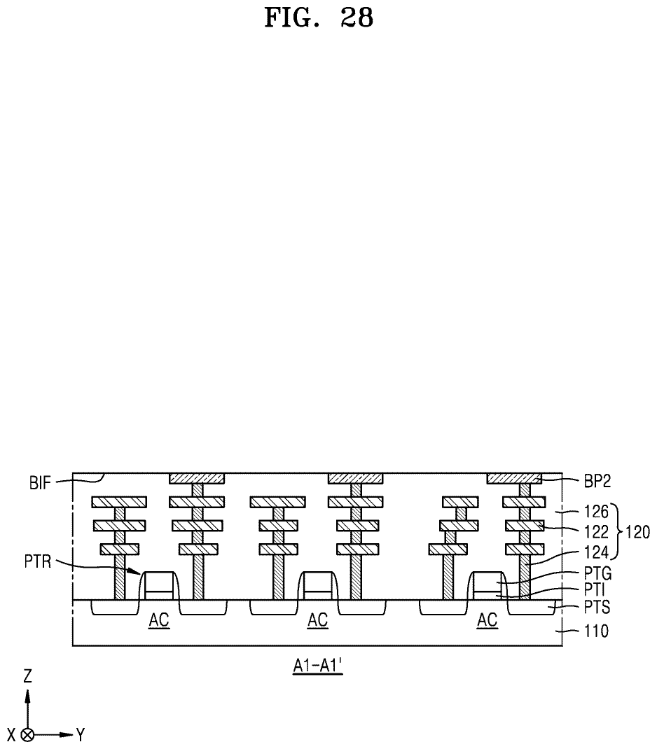

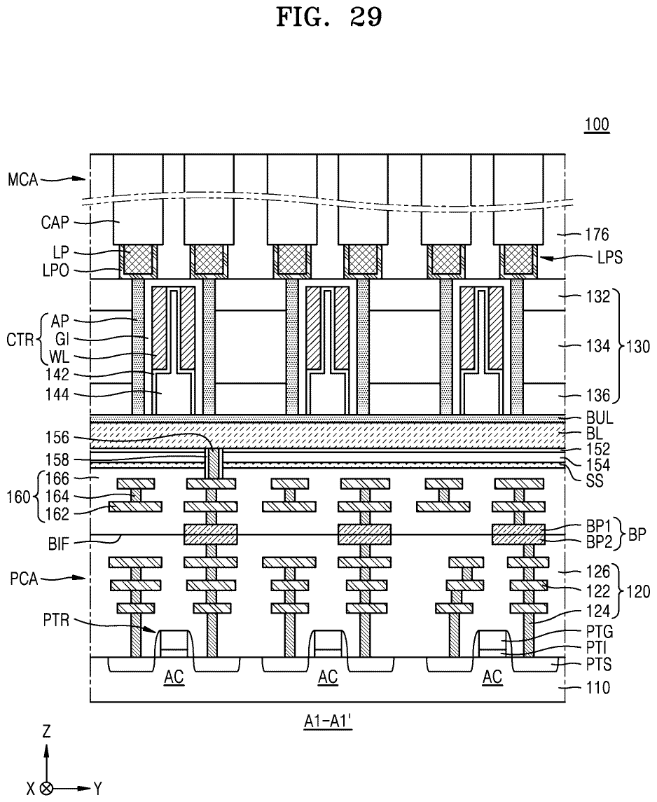

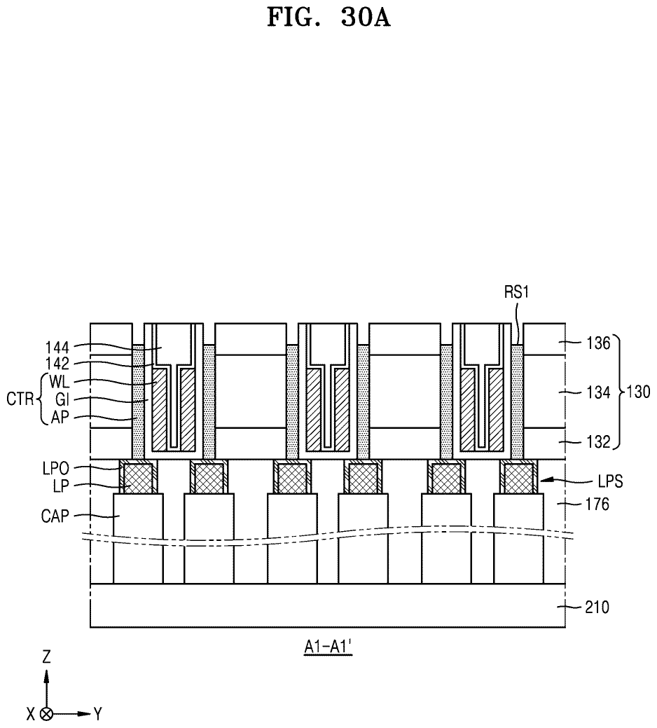

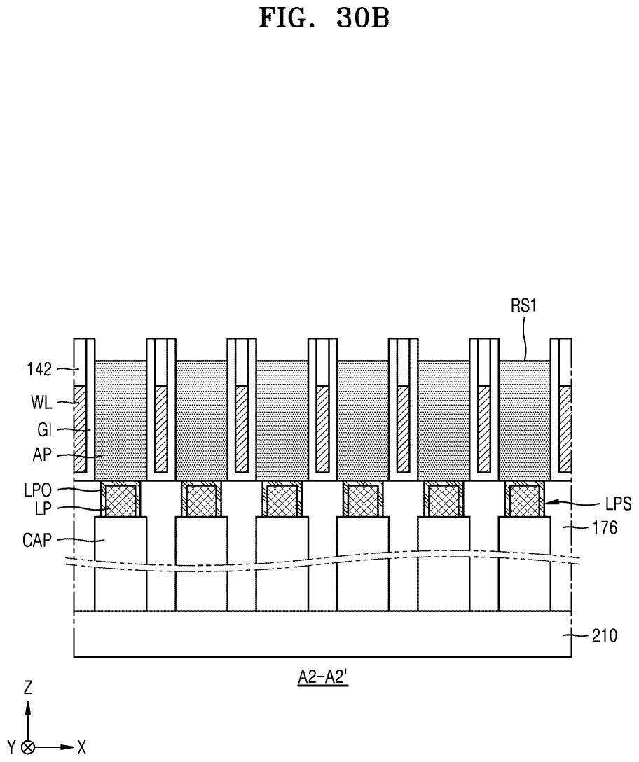

FIGS. 30A, 30B, 31A, 31B, 32A, 32B, and 32C are diagrams sequentially illustrating a method of manufacturing a semiconductor device according to some embodiments.

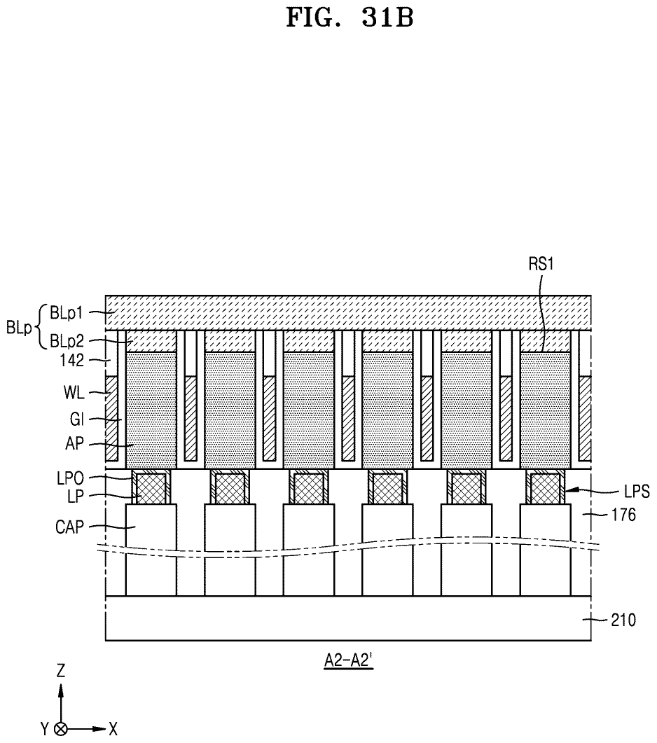

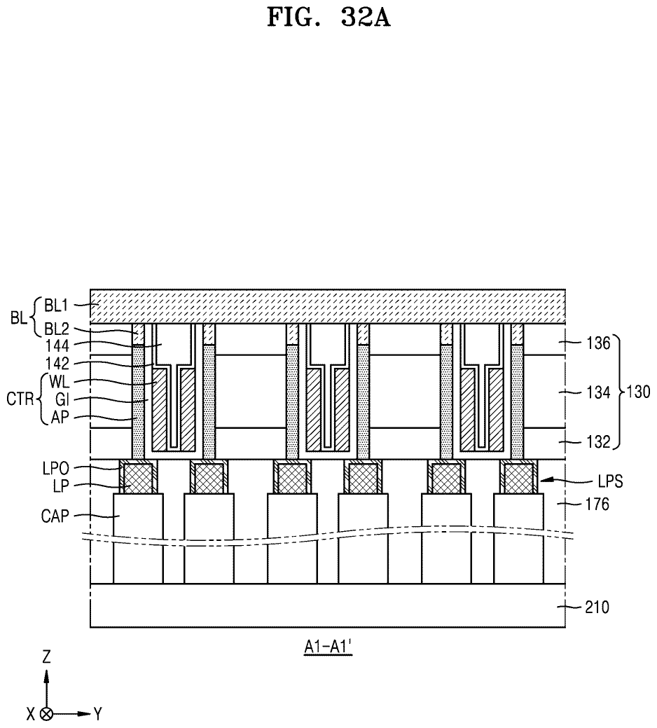

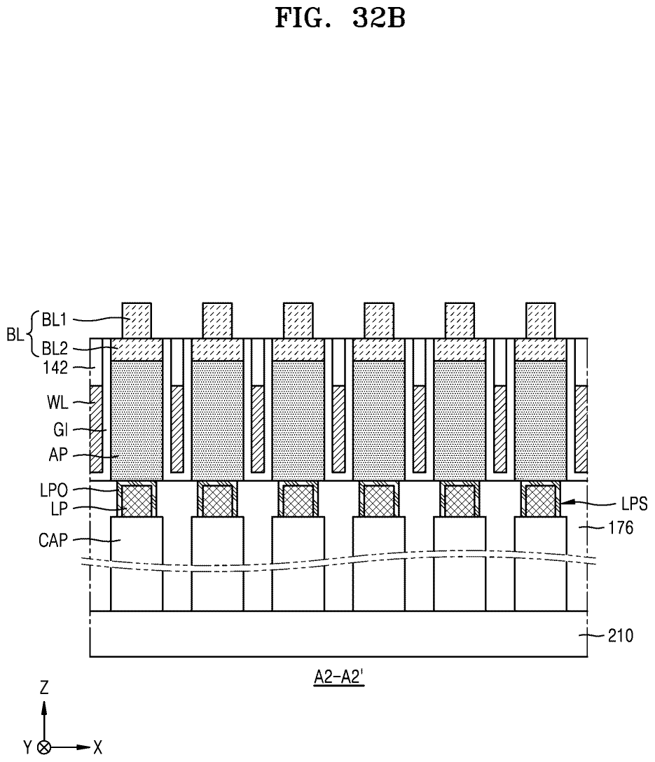

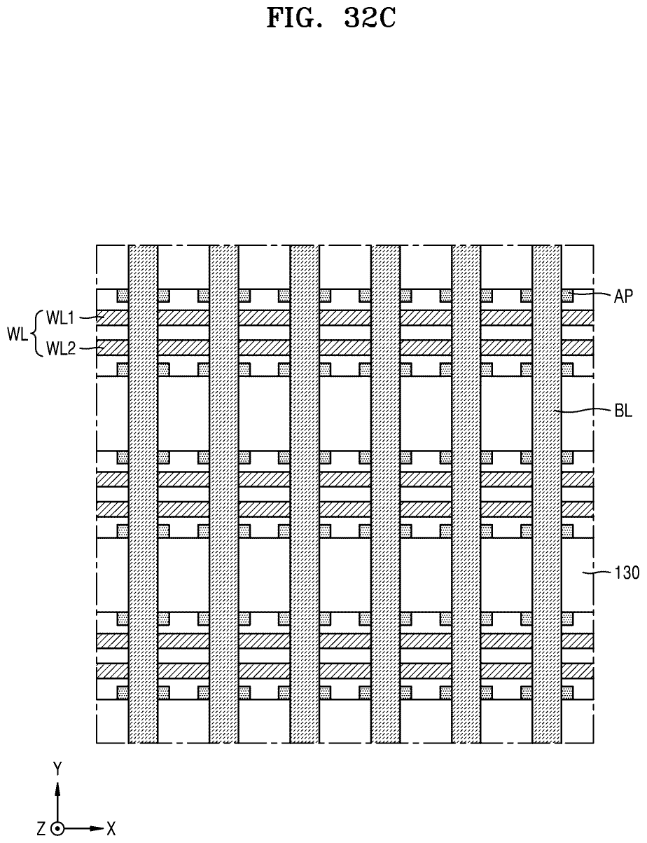

Specifically, FIGS. 30A and 30B are diagrams illustrating a process after FIGS. 23A and 23B, and FIGS. 32A, 32B, and 32C are diagrams illustrating a process before FIGS. 26A, 26B, and 26C.

Referring to FIGS. 30A and 30B, from the resultant of FIGS. 23A and 23B, the upper portion of the channel layer AP may be removed to form the recess RS1. The sidewall of the recess RS1 may include a portion of the sidewall of the first mold layer 136, and the bottom surface of the recess SRI may include the top surface of the channel layer AP.

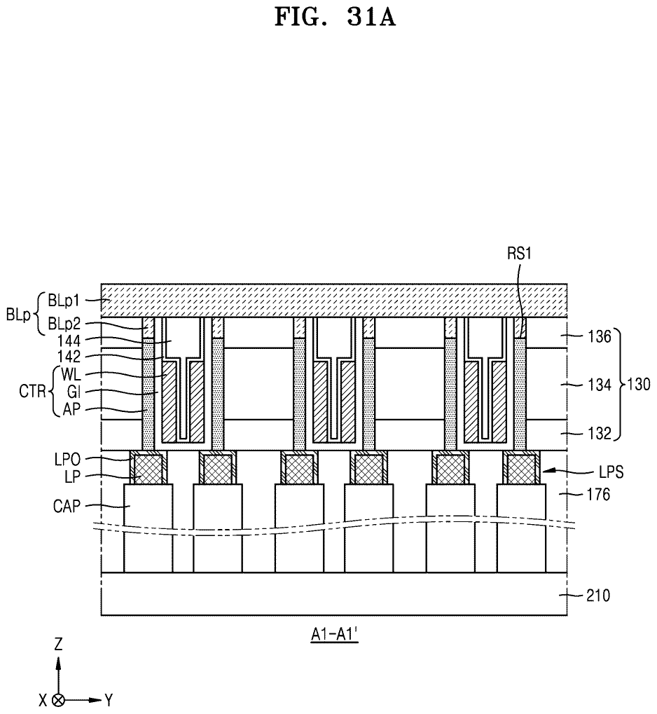

Referring to FIGS. 31A and 31B, the bit line layer BLp may be formed on the recess RS1 and the mold structure 130. In some embodiments, the bit line layer BLp may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, and/or combinations thereof. The bit line layer BLp may include a first bit line layer BLp1 extending in the first horizontal direction (e.g., X direction) and the second horizontal direction (e.g., Y direction), and a second bit line layer BLp2 extending from the first bit line layer BLp2 in the vertical direction (e.g., Z direction) to partially or completely fill the landing pad recess RS2.

Referring to FIGS. 32A, 32B and 32C, the plurality of mask patterns spaced apart from each other in the first horizontal direction (e.g., X direction) and extending in the second horizontal direction (e.g., Y direction) may be formed on the bit line layer BLp (see FIG. 31A), and the bit line layer BLp may be patterned using the plurality of mask patterns as the etching mask to form the bit line BL.

Thereafter, the semiconductor device 200 described with reference to FIGS. 7, 8, and 9 may be completed through a manufacturing process similar to the manufacturing process described above with reference to FIGS. 26A, 26B, 26C, 27, 28, and 29.

According to the comparative example, as the landing pad is directly electrically connected to the channel layer without an oxide semiconductor layer electrically connecting the landing pad to the channel layer and the contact area between the landing pad and the channel layer is relatively small (e.g., the contact area is within about 80 square nanometers to 100 square nanometers), the contact resistance between the landing pad and the channel layer may be relatively large.

According to some embodiments, as the oxide semiconductor layer LPO electrically connecting the landing pad LP to the channel layer AP is introduced and the oxide semiconductor layer LPO partially or completely surrounds the sidewalls and the bottom surface of the landing pad LP to increase the contact area between the oxide semiconductor layer LPO and the landing pad LP (e.g., the contact area is within about 500 nanometers to about 550 nanometers), the contact resistance between the landing pad LP and the channel layer AP may be reduced by the oxide semiconductor layer LPO, thereby providing the semiconductor device with relatively improved electrical characteristics.

While the inventive concept has been particularly shown and described with reference to embodiments thereof, it will be understood that various changes in form and details may be made without departing from the scope of the following claims.

What is claimed is:

1. A semiconductor device, comprising:
a peripheral circuit area; and
a cell array area on the peripheral circuit area, wherein the cell array area comprises:
a mold structure extending in a first horizontal direction;
a channel layer on a sidewall of the mold structure, wherein the channel layer comprises a first oxide semiconductor material;
a word line on a sidewall of the channel layer;
a landing pad on a top surface of the channel layer;
a bit line on a bottom surface of the channel layer opposite the top surface, wherein the bit line extends in a second horizontal direction that intersects the first horizontal direction;
an oxide semiconductor layer on one or more sidewalls and a bottom surface of the landing pad, wherein the oxide semiconductor layer comprises a second oxide semiconductor material; and
a cell capacitor electrically connected to the channel layer through the landing pad and the oxide semiconductor layer.

2. The semiconductor device of claim 1, wherein each of the first oxide semiconductor material and the second oxide semiconductor material comprises at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O) or zirconium zinc tin oxide (Zr_{X}Zn_{y}Sn_{z}O).

3. The semiconductor device of claim 1, wherein the top surface of the channel layer is coplanar with a top surface of the mold structure, and
wherein the bottom surface of the channel layer is coplanar with a bottom surface of the mold structure.

4. The semiconductor device of claim 1, further comprising an intermediate line between the channel layer and the bit line,
wherein the intermediate line extends in the second horizontal direction and comprises a third oxide semiconductor material.

5. The semiconductor device of claim 4, wherein the third oxide semiconductor material comprises at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O) or zirconium zinc tin oxide (Zr_{X}Zn_{y}Sn_{z}O).

6. The semiconductor device of claim 4, further comprising:
a shield metal layer on the bit line; and
a bit line insulating layer on a sidewall of the bit line and a sidewall of the intermediate line,
wherein the bit line insulating layer is between the shield metal layer and the bit line and between the shield metal layer and the intermediate line.

7. The semiconductor device of claim 1, wherein the top surface of the channel layer is coplanar with a top surface of the mold structure, and
wherein the bottom surface of the channel layer is non-coplanar with a bottom surface of the mold structure.

8. The semiconductor device of claim 1, wherein the bit line comprises:
a first bit line extending in the second horizontal direction; and
a second bit line extending in a vertical direction between the first bit line and the channel layer.

9. The semiconductor device of claim 1, wherein the oxide semiconductor layer comprises:
a first oxide semiconductor layer on the one or more sidewalls of the landing pad; and
a second oxide semiconductor layer on the bottom surface of the landing pad,
wherein the first oxide semiconductor layer comprises a different material than the second oxide semiconductor layer.

10. The semiconductor device of claim 1, wherein the oxide semiconductor layer comprises:
a first oxide semiconductor layer on the one or more sidewalls of the landing pad; and
a second oxide semiconductor layer on the bottom surface of the landing pad,
wherein a thickness of the first oxide semiconductor layer is different from a thickness of the second oxide semiconductor layer.

11. A semiconductor device, comprising:
a peripheral circuit area comprising a substrate and a peripheral circuit transistor; and
a cell array area on the peripheral circuit area, wherein the cell array area comprises:
a mold structure extending in a first horizontal direction;
a channel layer on a sidewall of the mold structure, wherein the channel layer comprises a first oxide semiconductor material;
a word line on a sidewall of the channel layer;
a gate insulating layer between the channel layer and the word line;
a landing pad on a top surface of the channel layer;
an oxide semiconductor layer on one or more sidewalls and a bottom surface of the landing pad, wherein the oxide semiconductor layer comprises a second oxide semiconductor material;
a cell capacitor separated from the channel layer in a vertical direction by the landing pad and the oxide semiconductor layer;
a bit line on a bottom surface of the channel layer opposite the top surface and extending in a second horizontal direction that intersects the first horizontal direction;
a bit line insulating layer on the bit line; and
a shield metal layer separated from the bit line by the bit line insulating layer.

12. The semiconductor device of claim 11, wherein each of the first oxide semiconductor material and the second oxide semiconductor material comprises at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), or zirconium zinc tin oxide (Zr_{X}Zn_{y}Sn_{z}O).

13. The semiconductor device of claim 11, further comprising an intermediate line between the bit line and the channel layer and between the bit line and the mold structure,
wherein the intermediate line extends in the second horizontal direction and comprises a third oxide semiconductor material.

14. The semiconductor device of claim 13, wherein the intermediate line is on the bit line insulating layer, and
wherein the bit line insulating layer is between the intermediate line and the shield metal layer.

15. The semiconductor device of claim 13, wherein the third oxide semiconductor material comprises at least one of zinc tin oxide (ZnₓSn_{y}O), indium zinc oxide (InₓZn_{y}O), zinc oxide (ZnOₓ), indium gallium zinc oxide (In_{X}Ga_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (Sn_{X}In_{y}Zn_{z}O), aluminum tin indium zinc oxide (Al_{X}Sn_{y}In_{z}ZnₐO), silicon indium zinc oxide (Si_{X}In_{y}Zn_{z}O), aluminum zinc tin oxide (Al_{X}Zn_{y}Sn_{z}O), gallium zinc tin oxide (Ga_{X}Zn_{y}Sn_{z}O), or zirconium zinc tin oxide (Zr_{X}Zn_{y}Sn_{z}O).

16. The semiconductor device of claim 11, wherein the bit line comprises:
a first bit line extending in the second horizontal direction; and
a second bit line extending in the vertical direction between the first bit line and the channel layer.

17. The semiconductor device of claim 11, wherein the oxide semiconductor layer comprises:
a first oxide semiconductor layer on the one or more sidewalls of the landing pad; and
a second oxide semiconductor layer on the bottom surface of the landing pad,
wherein the first oxide semiconductor layer comprises a different material than the second oxide semiconductor layer and
wherein a thickness of the first oxide semiconductor layer is different from a thickness of the second oxide semiconductor layer.

18. A method of manufacturing a semiconductor device, the method comprising:
forming a peripheral circuit area and forming a cell array area on the peripheral circuit area, wherein the forming of the cell array area comprises:
forming a cell capacitor and a first insulating layer on a sidewall of the cell capacitor on a carrier substrate;
forming a landing pad on the cell capacitor;
forming a first oxide semiconductor layer on one or more sidewalls of the landing pad;
forming a second insulating layer on the first oxide semiconductor layer;
performing an etch-back process on a top surface of the landing pad to form a landing pad recess;
forming a second oxide semiconductor layer in the landing pad recess; and
forming a mold structure on the first oxide semiconductor layer, the second oxide semiconductor layer, and the second insulating layer,
forming a channel layer on a sidewall of the mold structure, forming a word line on a sidewall of the channel layer, and forming a bit line on a bottom surface of the channel layer.

19. The method of claim 18, further comprising, after the forming of the second oxide semiconductor layer, performing a surface treatment process on the first oxide semiconductor layer and the second oxide semiconductor layer using fluorine (F), boron (B), or argon (Ar).

20. The method of claim 18, wherein the first oxide semiconductor layer comprises a different material than the second oxide semiconductor layer.
